(19) United States
(12) Patent Application Publication
(10) Pub. No.: US 2024/0381790 A1
(43) Pub. Date: Nov. 14, 2024

(54) TECHNIQUES AND APPARATUSES FOR PROCESSING CHALCOGENIDES

(71) Applicant: Lam Research Corporation, Fremont, CA (US)

(72) Inventors: John Hoang, Fremont, CA (US); Aaron Lynn Routzahn, Fremont, CA (US); Andreas Fischer, Castro Valley, CA (US); Meihua Shen, Fremont, CA (US); Thorsten Bernd Lill, Kalaheo, HI (US); Seshasayee Varadarajan, Lake Oswego, OR (US)

(21) Appl. No.: 18/688,678

(22) PCT Filed: Sep. 4, 2022
(86) PCT No.: PCT/US2022/042570

§ 371 Date: Mar. 1, 2024

Related U.S. Application Data
(60) Provisional application No. 63/260,946, filed on Sep. 7, 2021.

(51) Int. Cl. H10N 70/00; H10B 63/10; H10N 70/20

(52) U.S. Cl. CPC H10N 70/063; H10N 70/023; H10N 70/231; H10N 70/8828; H10B 63/10

(57) ABSTRACT

A layer of a chalcogenide material can be etched by providing a wafer having a layer of the chalcogenide material to a processing chamber, heating the wafer to a first temperature, modifying a surface of the layer of chalcogenide material by flowing a first chemical species comprising a fluoride or a chloride onto the wafer to create a modified layer of chalcogenide material while the wafer is at the first temperature, and removing the modified layer of chalcogenide material, without using a plasma, by flowing a second chemical species comprising a compound with a center atom that is aluminum, boron, silicon, or germanium, and with at least one chlorine, onto the wafer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication involves formation of memory stacks, which can be difficult to form and are often sensitive to etching processes, such as exposure to energetic species, and sensitive to oxidation, moisture, and additional exposure to energetic species after etching. As a result, some memory stacks undergo post-etching processes to address damage from etching and exposure to the environment, which may be followed by encapsulation of the memory stacks prior to subsequent processing. However, some methods of post-etching processing before encapsulation, and the corresponding apparatuses, may not be unable to sufficiently address the damage and exposures to the memory stacks and may further damage the memory stacks.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

The systems, methods and devices of this disclosure each have several innovative aspects, no single one of which is solely responsible for the desirable attributes disclosed herein. Included among these aspects are at least the following implementations, although further implementations may be set forth in the detailed description or may be evident from the discussion provided herein.

### BRIEF DESCRIPTION OF THE DRAWINGS

FIG. 1 depicts an example process flow diagram for performing operations in accordance with disclosed embodiments.

FIG. 2 depicts a second example process flow diagram for performing operations in accordance with disclosed embodiments.

FIG. 3 depicts an example schematic illustration of atomic layer etching in accordance with disclosed embodiments.

FIG. 4 depicts a third example process flow diagram for performing operations in accordance with disclosed embodiments.

FIGS. 5A through 5C depict example gas flow sequences according to various embodiments.

FIG. 6 depicts an example schematic illustration of etching in accordance with disclosed embodiments.

FIG. 7 depicts an example process flow of etching a chalcogenide.

FIG. 8 depicts a flowchart of an example sequence of operations for forming a film of material on a substrate via an ALD process.

FIG. 9 depicts a third example process flow diagram for performing operations in accordance with disclosed embodiments.

FIG. 10 depicts a first example processing apparatus according to disclosed embodiments.

FIG. 11 depicts yet another example process flow of etching layers of a chalcogenide.

FIG. 12 depicts a second example processing apparatus according to disclosed embodiments.

FIG. 13 depicts another technique in accordance with disclosed embodiments.

FIG. 14 depicts yet another technique in accordance with disclosed embodiments.

FIG. 15 depicts an example process flow of etching two chalcogenides.

FIG. 16 depicts an example of a substrate processing chamber for etching materials according to the present disclosure.

FIG. 17 depicts a cross-sectional side view of an example apparatus in accordance with disclosed embodiments.

FIG. 18 depicts a top view of a substrate heater with a plurality LEDs.

FIG. 19 provides an example temperature control sequence.

FIG. 20 schematically shows an embodiment of a process station that may be used to deposit material.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards, magnetic recording media, magnetic recording sensors, mirrors, optical elements, micro-mechanical devices and the like.

### Introduction and Context

Semiconductor fabrication processes often involve deposition of silicon nitride material. In one example, silicon nitride may be used in semiconductor device fabrication as diffusion barriers, gate insulators, sidewall spacers, and encapsulation layers. Conformal silicon nitride layers may also be used in other applications. For example, silicon nitride may be used during fabrication of memory structures. Some memory structures include metal oxide materials used for bit storage. However, as advanced memory structures are developed to accommodate smaller device sizes and improve efficiency, new challenges arise. Advanced memory architectures such as magnetoresistive random-access memory and phase change random-access memory (PCRAM) rely on new materials (other than metal oxides), such as chalcogenides, for bit storage.

In some memory devices, a chalcogenide, such as an ovonic threshold switching (OTS) chalcogenide, is present on the stack. The OTS and other chalcogenides may be sensitive to various gases and plasmas. In the case of PCRAM for example, the phase of a metal chalcogenide determines the bit state. Some example chalcogenides include sulfur (S), selenium (Se), and tellurium (Te). These new materials are air and moisture sensitive and may require encapsulation layers. When combined with appropriate metalloid ions such as germanium (Ge), antimony (Sb), etc., these chalcogenides form a phase change layer. In some cases, the memory device includes a germanium antimony tellurium (GST) material. If damaged, the chalcogenide may not function properly; for instance, the phase change layer may not change phases.

Using chalcogenides requires both depositing the chalcogenide and removing portions of the deposited chalcogenide from a wafer, such as removing some of the chalcogenide from within a trench or via, to create the desired structure. It is desirable to etch the chalcogenide within desirable nonuniformity tolerances, but without damaging and/or altering the composition of the chalcogenide material that is intended to remain on the wafer. However, removing some chalcogenides from a wafer poses unique and difficult challenges and considerations, and conventional etching is unable to remove some chalcogenides within desirable nonuniformity tolerances without damaging and/or altering the composition of the chalcogenide material.

Some of the conventional techniques for removing chalcogenides may also adversely affect the wafer. For example, reactive-ion etching (“RIE”) that uses a plasma sometimes results in poor etching uniformity as well as unwanted damage to the chalcogenide which can diminish its properties and prevent it from being an effective PCRAM. The plasma in RIE etching is also directional, not isotropic, thereby limiting its ability to etch in a direction perpendicular to the substrate surface preventing it from etching under shelves or overhangs. For instance, wafers may have “features” such as via or contact holes, which may be characterized by one or more of narrow and/or re-entrant openings, constrictions within the feature, and high aspect ratios One example of a feature is a hole or via in a semiconductor substrate or a layer on the substrate. Other examples include a trench in a substrate or layer, as well as overhangs or shelves that may require an etch in a location that may not be accessible with directional ions used in RIE etching.

Some processes that use RIE etching require performing post-etching operations, sometimes referred to as “clean” or “cleaning” operations, to remove at least some of the damaged chalcogenide material. However, these cleaning operations can reduce throughput, increase costs, further damage the wafer, and can be difficult to implement. Some such cleaning operations utilize a wet cleaning process in which a wafer is exposed to numerous liquid chemicals that remove the damaged chalcogenide material from the surface of the wafer. However, wet cleaning processes can damage the wafer in various manners. In some instances, the liquid chemicals themselves may change the composition of some chalcogenide materials, such as GST, which can further damage the chalcogenide. Additionally, the capillary forces exerted by the wet cleaning liquids on structures with chalcogenides, such as liquid within a trench or via, can cause the structure to collapse. Some wet cleaning processes may avoid this collapse by using surface modification reactants, but these reactants can remain on the surface of the chalcogenide and adversely affect the chalcogenide or other materials on the wafer. The amount of damage removal is also dependent on the selectivity of the damaged chalcogenide to the undamaged bulk chalcogenide, thereby increasing the challenge and difficult of removing the damaged chalcogenide.

Further, the liquids used in wet cleaning processes can be costly and require a complex liquid storage and delivery system that can be difficult to operate and maintain. Further, wet cleaning operations are performed at atmospheric pressure while many etching and post-etching processes, such as deposition of the encapsulation layer onto the etched chalcogenides, are performed at vacuum pressures. Wafers are therefore transferred from a vacuum environment in which the etching is performed, to atmospheric pressure for the wet cleaning, and then back to the vacuum environment for further post-etching processes. Transferring the wafer between vacuum and atmospheric environments increases processing time which decreases throughput, can lead to wafer defects through particle contamination, and can expose the etched chalcogenide material to air, oxygen, or N2, and therefore oxidize and damage the etched chalcogenide material. Wet cleaning operations are also generally performed in a separate chamber which, along with the complex liquid storage and delivery system, requires additional space in a fabrication environment, thereby enlarging the footprint of the semiconductor processing tool and preventing additional tools from being positioned in the facility and thereby decreasing overall throughput within the facility.

Provided herein are techniques and apparatuses for etching and further processing chalcogenide materials. The techniques use thermal etching, which may include thermal atomic layer etching, to perform the cleaning operations of the chalcogenide materials after RIE etching or other ion-based etching, instead of the wet cleaning operations, and/or to etch the bulk chalcogenide material instead of the RIE or other ion-based etching. This may include performing thermal etching on a single layer of chalcogenide material or multiple layers of chalcogenide in a stack of materials. As explained in greater detail below, thermal etching may modify a surface of a layer of chalcogenide material by flowing a first chemical species having a fluoride or a chloride onto the wafer to create a modified layer of chalcogenide material, and remove the modified layer of chalcogenide material, without using a plasma, by flowing a second chemical species comprising a compound with a center atom that is aluminum, boron, silicon, or germanium, and with at least one chlorine, onto the wafer.

Atomic layer etching (“ALE”) processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts, as well as a cleaning operation to remove residues that have built up on surfaces of the processing chamber. Generally, a cycle contains one instance of a unique sequence of operations.

As an example, an ALE cycle may include the following operations: (i) delivery of a first process gas that is a reactant gas, (ii) purging of the reactant gas from the chamber, (iii) delivery of a second process gas that is a removal gas and an optional plasma, and (iv) purging of the chamber. The modification operation (item (ii) above) generally forms a thin, reactive surface layer with a thickness less than the un-modified material, such as one, two, or three, atomic layers thick, for instance, or less than a whole atomic layer in one cycle.

The etching processes described herein may rely upon chemical reactions in conjunction with maintaining the substrate at a particular temperature or temperature range to drive chemical reactions in the modification and/or the removal operations which may be considered “thermal ALE” or “thermal etching”. In some embodiments, the thermal etching or thermal ALE may be considered an isotropic etch. In some embodiments, one or more layers of the substrate may be modified with chemical adsorption (hereinafter “chemisorption”), not with a plasma, while the substrate is maintained at a first temperature, after which the one or more modified layers of the substrate may be removed with desorption, not with a plasma, while the substrate is at a second temperature. Some implementations may optionally use a plasma during the modification operation and not during the removal operation. In some embodiments the first and second temperatures may be the same, while in some other embodiments they may be different than each other.

Chemisorption and desorption are temperature dependent chemical reactions that may occur in separate temperature regimes, may occur in partially overlapping temperature regimes, or may occur in the same temperature regime. Because of this, some of the thermal etching techniques described herein maintain the temperature of the substrate at the same, or substantially the same (e.g., within about 10% or 5% of each other), temperature during the modification and removal operations. Some other embodiments modulate the temperature of the substrate between the modification and removal operations in order to enable and utilize chemisorption that occurs at one temperature for the modification operation, and to enable and utilize desorption that occurs at a different temperature for the removal operation.

In some thermal etching processes provided herein, one or more surface layers of material are modified by chemisorption while the substrate is maintained at a first temperature; this may result in the creation of one or more modified surface layers of the substrate. The substrate includes layers of material and exposed surfaces that may be a uniform layer of material or may be a non-uniform layer that includes different molecules and elements. A first process gas with modifying molecules may be flowed onto the substrate that is maintained at the first temperature. In some embodiments, the modifying molecules may include a fluorine or a chlorine, as described below, in order to fluorinate or chlorinate molecules on the substrate. The first process gas may also include a carrier gas, such as N₂, Ar, He, and Ne. This first temperature allows for chemisorption between the modifying molecules and at least some of the molecules in the exposed surface(s) of material.

The one or more modified surface layers may be removed while the substrate is maintained at the second temperature. In some embodiments, the second temperature alone may enable and cause desorption of the modified molecules from the substrate thereby removing the modified molecules from the substrate. In some other embodiments, a second process gas with removal molecules may be flowed onto the substrate, including onto the exposed surfaces of the substrate. The second process gas may also include a carrier gas as described above. These removal molecules may react with the modified molecules to form a different volatile molecule, which may be considered a volatized molecule. This volatized molecule may in turn be removed from the substrate by desorption when the substrate is at the second temperature. In some embodiments, this flowing of the second process gas may be part of the removal operation or may be a separate operation that occurs before, after, or during the heating of the substrate.

In some embodiments, thermal ALE may be isotropic and thus non-directional. In some other embodiments thermal ALE is not isotropic when directional ions are used in the etching process, such as during the modification operation.

Other thermal etching may be performed in which the modifying and removal molecules are at least co-flowed onto the substrate, and thus the modification and removal operations at least partially overlap. One or more process gases containing both modifying molecules and removal molecules may be simultaneously flowed onto the wafer during such processing. In many implementations of this thermal etching, the modifying molecules and the removal molecules have limited to no adverse reaction with each other, such that they may be co-flowed onto the substrate. In some instances, this co-flow may occur for all of the etching while in other instances, the co-flow may only occur for a part of the etching. In some examples having only partially overlapping flows, the modifying molecules may be flowed onto the substrate before the removal molecules are flowed onto the substrate, after which both the modifying molecules and the removal molecules may be simultaneously flowed onto the substrate. In some instances, the flow of both the modifying molecules and the removal molecules may stop at substantially the same time (e.g., within about 10% or 5% of each other) while in other instances, the flow of modifying molecules may stop and the removal molecules may be flowed onto the substrate.

The techniques provided herein may also deposit one or more encapsulation materials onto the etched chalcogenide. This may include depositing encapsulation material using chemical vapor deposition (“CVD”), plasma-enhanced CVD (“PECVD”), or atomic layer deposition (“ALD”) in a processing chamber separate from the processing chamber in which etching is performed. Some embodiments may transfer the wafer between these processing chambers without exposing the wafer to atmospheric pressure such that the wafer remains at a vacuum pressure in both processing chambers and during transfer between the processing chambers. In some embodiments, a layer of a first encapsulation material may be deposited on the etched chalcogenide while the wafer remains in the processing chamber in which etching is performed, and the first encapsulation material may include an aluminum, such as aluminum oxide. After the first encapsulation material is deposited, the wafer may be transferred to another processing chamber where additional encapsulation material is deposited on the wafer.

### Thermal Etching and Encapsulation Techniques

Aspects of this disclosure relate to thermal etching of one or more layers of chalcogenide material. As provided above, thermal etching processes rely upon chemical reactions in conjunction maintaining the substrate at a particular temperature or temperature range to drive chemical reactions in the modification and/or the removal operations. In some embodiments, the thermal etching or thermal ALE may be considered an isotropic etch, i.e., a non-directional etch. In some embodiments, one or more layers of the substrate may be modified with chemisorption, not with a plasma, while the substrate is maintained at a first temperature, after which the one or more modified layers of the substrate may be removed with desorption, not with a plasma, while the substrate is at a second temperature. Some implementations may optionally use a plasma during the modification operation and not during the removal operation. In some embodiments the first and second temperatures may be the same, while in some other embodiments they may be different than each other.

Some of the techniques described herein etch a chalcogenide material by performing a modification operation in which a first chemical species containing a fluorine, such as hydrogen fluoride, or a chlorine, such as hydrogen chloride, is flowed onto the wafer to modify the surface of a layer of the chalcogenide and form a modified layer of the chalcogenide material. The first chemical species having the fluoride or chloride may be considered the modifying molecules described herein. This modification converts a layer of the chalcogenide to a fluorinated chalcogenide or chlorinated chalcogenide. The modified layer of chalcogenide is reactive and can be removed by flowing a second chemical species containing a compound with a center atom that is aluminum, boron, silicon, or germanium, and with at least one chlorine, onto the wafer. The compound in the second chemical species reacts with the fluorinated chalcogenide or chlorinated chalcogenide to form volatile molecules that desorb from the wafer.

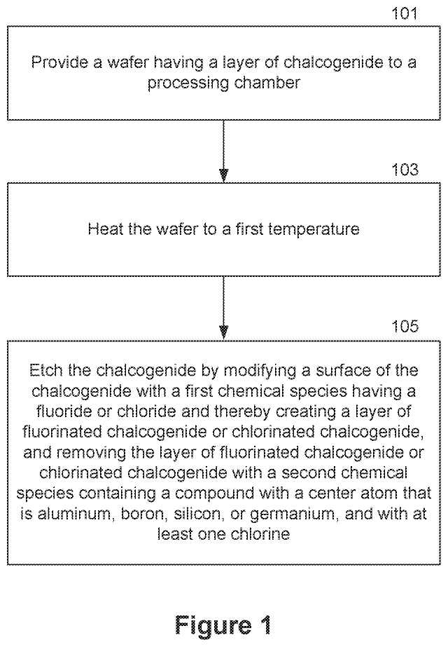

FIG. 1 depicts an example process flow diagram for performing operations in accordance with disclosed embodiments. In block 101, a wafer is provided to a processing chamber configured to performing etching of the wafer. The wafer may have a layer of chalcogenide deposited thereon, and in some instances, a surface of the layer of chalcogenide may be exposed to the processing chamber environment. On the wafer, this chalcogenide may also be positioned along the sidewalls and/or bottom of a hole, via, or trench, on the underside of shelves or features, and/or on the top surface of a feature. In some such implementations, isotropic thermal etching, including thermal ALE, is advantageous because it can perform non-directional, non-line-of-sight etching to reach areas with high aspect ratios and areas out of sight, such as under shelves or overhangs.

The chalcogenide may be any of those listed herein. In some implementations, the chalcogenide may be a phase change material, such as a germanium (Ge) antimony (Sb) tellurium (Te) (collectively “GST” or “GeSbTe”) material. This may also include n-doped GeSbTe compounds (N-GST), Sb₂Te, and Sb₂Te doped with Ag and In (AIST). As provided above, phase change materials are advantageous for use in forming memory devices because, for instance, the phase of a metal chalcogenide determines the bit state. In some embodiments, the chalcogenide may include those that do not change phase, such as an ovonic threshold switching (OTS) material which may include a compound with germanium, arsenic, and selenium (GeAsSe) or a compound containing germanium, antimony, selenium and nitrogen (GeSb,Se,N), for example.

In block 103, the wafer is heated to a first temperature which may be, as provided herein, considered both a specific temperature, or may be a temperature range. In some embodiments, the first temperature may be between about 20° C. and about 500° C., about 20° C. and about 150° C., about 20° C. and about 80° C., about 20° C. and about 100° C., about 100° C. and about 450° C., about 100° C. and about 400° C., about 150° C. and about 400° C., about 200° C. and about 600° C., about 200° C. and about 500° C., about 200° C. and about 350° C., or about 350° C. and about 500° C., for example. As discussed in more detail below, the wafer may be maintained at the first temperature during all, or substantially all (e.g., at least 80%, 90%, or 95%), of the etching, of the modification operation, and/or the removal operation.

In block 105, the layer of chalcogenide on the wafer is etched by modifying a surface of the layer of chalcogenide by flowing a first chemical species having a fluoride or a chloride onto the wafer and to create a layer of fluorinated chalcogenide or chlorinated chalcogenide, and removing the layer of fluorinated chalcogenide or chlorinated chalcogenide by flowing a second chemical species having a compound with a center atom that is aluminum, boron, silicon, or germanium, and with at least one chlorine. Some implementations may have separate modification and removal operations that may, in some instances, be separated by a purge operation. These implementations may be considered self-limited etching. Some other implementations may have at least partially overlapping modification and removal operations which may be performed, in some embodiments, by co-flowing the first species (i.e., the modifying molecules) and the second species (i.e., the removal molecules) onto the wafer.

The first chemical species having a fluoride may include one or more of the following non-limiting examples: a hydrogen fluoride, such as HF, a sulfur fluoride, such as sulfur tetrafluoride or sulfur hexafluoride or sulfuryl fluoride (SO₂F₂), a nitrogen fluoride such as nitrogen trifluoride, and a xenon fluoride, such as xenon difluoride. The first chemical species having a chlorine may include one or more of the following non-limiting examples: a hydrogen chloride, such as HCl, a sulfur chloride, such as sulfur dichloride or sulfur tetrachloride or sulfuryl chloride (SO₂Cl₂), or a nitrogen chloride such as trichloramine (NCl₃). The use of a fluorine species or chlorine species, as opposed to other halogens or molecules, for modifying the surface of the layer of chalcogenide results in a unique reactive compound that enables and allows for the removal of all the chalcogenide when in the presence of the removal molecules because fluorine and chlorine bind very strongly to the surface and weaken the bonds to the underlayers. The first chemical species may be flowed in vapor form onto the wafer and may be flowed as a part of a process gas that may optionally include a carrier gas such as nitrogen, argon, helium, or neon, for instance.

The second chemical species having a compound with a center atom that is aluminum, boron, silicon, or germanium, and with at least one chlorine, may include various compounds. In some implementations, the compound may optionally include a hydrogen, a methyl group, or an ethyl group. For example, the compound may have an aluminum center atom along with a chlorine and a methyl group, such as dimethylaluminum chloride (DMAC), or trimethylaluminum (TMA) chloride. In another example, the compound may have a boron center along with multiple chlorides, such as boron trichloride (BCl₃). In yet another example, the compound may have a silicon center along with multiple chlorides, such as silicon tetrachloride (SiCl₄).

The compound of the second chemical species reacts with the fluorinated chalcogenide or chlorinated chalcogenide to cause its elements to become volatile and desorb from the wafer. For example, this exchange reaction is energetically favorable and therefore the fluorinated chalcogenide or chlorinated chalcogenide is able to form volatile compounds with the compound through, for example, transfer of chlorine, or through combining to form volatile germanium, antimony and tellurium compounds containing a combination of fluorides and chlorides. The second chemical species may also be flowed in vapor form onto the wafer and may be flowed as a part of a process gas that may be optionally include a carrier gas such as nitrogen, argon, helium, or neon, for instance.

In some embodiments, the etching of block 105 may be performed under various process conditions that enable such etching. In addition to the temperature ranges provided above, some implementations may maintain the substrate at a temperature between about 20° C. and about 500° C., about 20° C. and about 150° C., about 20° C. and about 80° C., about 20° C. and about 100° C., about 100° C. and about 450° C., about 100° C. and about 400° C., about 150° C. and about 400° C., about 200° C. and about 600° C., about 200° C. and about 500° C., about 200° C. and about 350° C., or about 350° C. and about 500° C., for example, during the etching. The etching may also be performed while the processing chamber is maintained at a pressure of between about 20 millitorr (mTorr) and 760 Torr (1 atm), including between about 20 mTorr and 600 mTorr, about 30 mTorr and 500 mTorr, and about 40 mTorr and 400 mTorr, as well as between about 3 Torr and 8 Torr, and about 4 Torr and 8 Torr, 2 Torr and 10 Torr, and 100 Torr and 760 Torr, for example. As discussed in more detail below, some implementations perform the etching of block 105 at substantially constant process conditions (e.g., with minor deviations, such as deviations of about 10% or 5% of the set conditions), while other implementations may vary one or more of the process conditions during the etching.

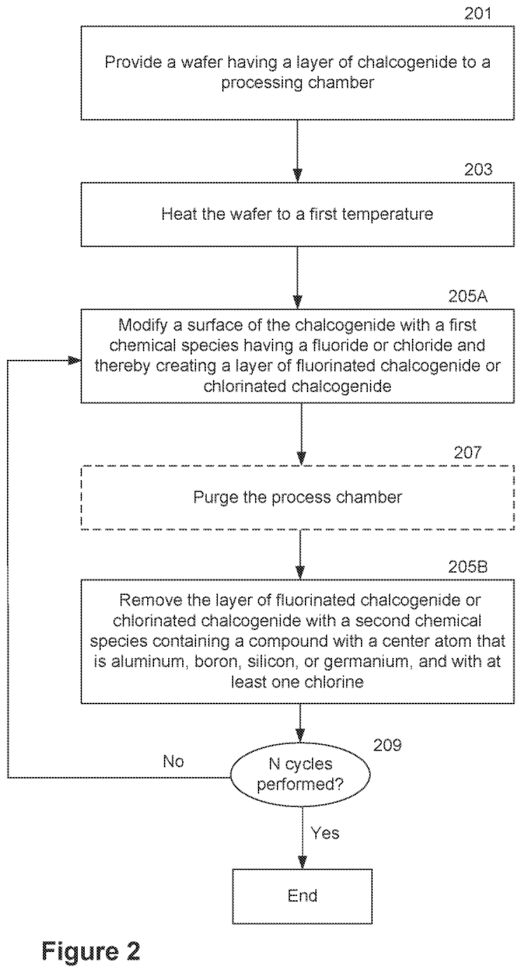

Some implementations may etch chalcogenide material using separate modification and removal operations. FIG. 2 depicts a second example process flow diagram for performing operations in accordance with disclosed embodiments. Here, block 201 and 203 are the same as blocks 101 and 103 in FIG. 1. In FIG. 2, the modification and removal operations of block 105 are performed as separate operations, blocks 205A and 205B, respectively. This may be considered self-limited etching, as well as ALE or thermal ALE.

Following block 203, a surface of the layer of chalcogenide is modified in block 205A, i.e., this block represents the modification operation. The layer of chalcogenide is modified as described above with respect to block 105 of FIG. 1, except that here, block 205A includes flowing a first process gas that includes the first chemical species having a fluoride or chloride onto the wafer. As with block 105, flowing the first chemical species onto the wafer modifies the surface of the layer of chalcogenide and creates a layer of fluorinated chalcogenide or chlorinated chalcogenide that is uniquely capable of being removed by exposure to and reactions with the second chemical species. This first chemical species in the first process gas may be any of those provided herein, including one or more of the following non-limiting examples: a hydrogen fluoride, such as HF, a sulfur fluoride, such as sulfur tetrafluoride or sulfur hexafluoride or sulfuryl fluoride, a nitrogen fluoride such as nitrogen trifluoride, and a xenon fluoride, such as xenon difluoride, a hydrogen chloride, such as HCl, a sulfur chloride, such as sulfur dichloride or sulfur tetrachloride or sulfuryl chloride, or a nitrogen chloride such as trichloramine (NCl₃). The first process gas may also be flowed in vapor form onto the wafer and may be optionally include a carrier gas such as nitrogen, argon, helium, or neon, for instance. The modification operation of block 205A may be stopped by stopping the flow of the first process gas to the wafer.

In some embodiments, an activation energy may be provided to assist with overcoming the activation barrier for the modifying molecule to adsorb on the wafer. This activation energy may be provided with thermal energy, radical energy, and/or UV photons, in some instances, which may include heating the wafer and/or generating a plasma or photons. This adsorption of the modifying molecule onto the first material may be considered chemical adsorption or “chemisorption” which is an energy dependent (e.g., a temperature dependent) chemical reaction. For some thermal etching techniques, this chemisorption during the modification operation may only occur at a particular temperature range that enables the activation barrier of the molecules in the layer of material and the incoming modifying molecules to be overcome which allows for dissociation and chemical bonding between these molecules and an adsorbate in the modifying molecule. Outside of this temperature range, the chemisorption may not occur, or may occur at undesirable (e.g., slow) rates.

Accordingly, some implementations of block 205A modify the surface layer of chalcogenide using only thermal activation energy, not a plasma. The first process gas is flowed onto the wafer that is maintained at the first temperature which provides the activation energy, and the chalcogenide is modified by chemisorption to from the modified layer of chalcogenide. The first temperature may be any temperature or temperature range provided herein, such as between about 20° C. and about 500° C., about 20° C. and about 150° C., about 20° C. and about 80° C., about 20° C. and about 100° C., about 100° C. and about 450° C., about 100° C. and about 400° C., about 150° C. and about 400° C., about 200° C. and about 600° C., about 200° C. and about 500° C., about 200° C. and about 350° C., or about 350° C. and about 500° C., for example. Additionally, the wafer may be maintained at the first temperature during all, or substantially all (e.g., at least 80%, 90%, or 95%), of the modification operation. The duration of the modification operation may be the duration for which modification of substantially all (e.g., at least 80%, 90%, or 95%) of desired exposed molecules on the substrate occurs. This may range from about 0.5 seconds to about 600 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

In some implementations, ionic energy, such as from a plasma, may be used to drive the modification operation of block 205A. In some instances, a plasma may be ignited and a fluorine or a chlorine may react with the wafer or may be adsorbed onto the surface of the wafer. The species generated from a plasma can be generated directly by forming a plasma in the process chamber housing the wafer or they can be generated remotely in a process chamber that does not house the wafer, and can be supplied into the process chamber housing the wafer.

After the modification operation of block 205A, the modified chalcogenide, i.e., the fluorinated chalcogenide or chlorinated chalcogenide, is removed from the wafer in block 205B. This removal is performed as described above with respect to block 105 of FIG. 1, expect that here, block 205B includes flowing a second process gas that includes the second chemical species having a compound with a center atom that is aluminum, boron, silicon, or germanium, and with at least one chlorine, onto the wafer. As with block 105, the second species reacts with the fluorinated chalcogenide or chlorinated chalcogenide and causes its constituents to desorb from, and thus be removed from, the wafer. This second chemical species in the second process gas may be any of those provided herein, such as DMAC, TMA, or BCl₃, for instance. The second process gas may also include a carrier gas such as nitrogen, argon, helium, or neon, for instance. The removal operation of block 205B may be stopped by stopping the flow of the second process gas to the wafer.

For desorption, a particular temperature range may enable the activation barrier of the modified molecule to be overcome which allows for the release of the modified layer from the wafer. In some examples, the temperature ranges at which chemisorption and desorption occur do not overlap while in others they may partially or fully overlap. Accordingly, in order to remove a molecule from a wafer using chemisorption and desorption, some implementations may maintain the wafer at the same, or substantially same (e.g., within about 1.0% or 5% of each other), temperature during the removal and modification operations. In order to remove a molecule from a wafer using chemisorption and desorption that occur in different temperature regimes, the modification operation of block 205A may occur in the first temperature range and the removal operation of block 205B may occur in the second different temperature range which may be higher or lower than the first temperature. Some such embodiments may perform multiple cycles to remove multiple layers of material by maintaining the wafer at the same, or substantially the same, temperature during the removal and modification operations, while other embodiments may repeatedly heat and cool the wafer between the two temperature regimes for chemisorption and desorption.

In some of the embodiments that use different temperature regimes, during or before block 205B, the temperature of the wafer may be brought to a second temperature that is different than the first temperature at which the wafer is maintained during the modification operation of block 205A. In some other embodiments, the second temperature is the same, or substantially the same (e.g., within about 10% or 5% of each other), temperature as the first temperature. This second temperature may be the temperature at which desorption occurs for the one or more modified surface layers. In some embodiments, the second temperature may be greater than the first temperature, and in these embodiments, block 205B may include heating the wafer from the first temperature to the second temperature. In some other embodiments, the second temperature may be less than the first temperature, and in these embodiments, the wafer may be actively cooled from the first temperature to the second temperature.

The wafer may be heated using radiant heating, convection heating, solid-to-solid heat transfer, or with a plasma. Additionally, the wafer top, bottom, or both, may be heated. The heating of the wafer may also occur in a non-linear fashion, in some embodiments, as discussed further below. As also described below, the wafer may be actively cooled in various manners. In some instances, a wafer may be heated to two different temperatures by positioning the wafer onto two separate substrate supports, such as heated pedestals, that are each maintained at a different temperature than each other. The wafer may therefore be heated to two different temperatures by being transferred between and placed at these two different substrate supports.

In block 205B, the one or more modified surface layers may be removed while the wafer is maintained at the second temperature. In some embodiments, the second temperature alone may enable and cause desorption of the modified molecules from the wafer thereby removing the modified molecules from the wafer.

In some embodiments, the second temperature may be between about 20° C. and about 500° C., about 20° C. and about 150° C., about 20° C. and about 80° C., about 20° C. and about 100° C., about 100° C. and about 450° C., about 100° C. and about 400° C., about 150° C. and about 400° C., about 200° C. and about 600° C., about 200° C. and about 500° C., about 200° C. and about 350° C., or about 350° C. and about 500° C., for example. Additionally, the wafer may be maintained at the temperature during all, or substantially all (e.g., at least 80%, 90%, or 95%), of the removal operation. The duration of the removal operation may be the duration for which desorption of substantially all (e.g., at least 80%, 90%, or 95%) of desired molecules on the wafer occurs. This may range from about 0.5 seconds to about 600 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

The performance of blocks 205A and 205B may be considered a single thermal ALE cycle. In some implementations, these blocks 205A and 205B may be repeated in order to perform multiple cycles and remove an atomic monolayer, a sub-monolayer, as well as multiple layers of the chalcogenide. Some embodiments remove a fraction of a monolayer in one cycle as some etch rates may be lower than the lattice constant of the material that is being etched. This may include performing, for example, about 1 to about 1,000 cycles, about 1 to about 500 cycles, about 1 to about 100 cycles, about 1 cycle to about 30 cycles, or about 1 to about 20 cycles. Any suitable number of ALE cycles may be included to etch a desired amount of chalcogenide film. In some embodiments, ALE is performed in cycles to etch about 1. Angstroms (Å) to about 50 Å of the surface of the layers on the wafer. In some embodiments, cycles of ALE etch between about 2 Å and about 50 Å of the surface of the layers on the wafer. In some embodiments, each ALE cycle may etch at least about 0.1 Å, 0.5 Å, 1 Å, 2 Å, or 3 Å. As further illustrated in FIG. 2, blocks 205A and 205B, and in some implementations an optional purge of block 207, may be repeated for N ALE, or etching, cycles. Once the decision step 209 determines that the N ALE cycles have been performed, the etching may be finished and thus it may end.

In some operations, an optional purge operation of block 207 may be performed after the modification operation of block 205A and before the removal operation of block 205B. In a purge operation, non-surface-bound active modifying molecules, such as the fluorine species or chlorine species, and/or other residue or particulates, may be removed from the process chamber, the chamber walls, the chamber gas volume, and/or the substrate. This can be done by purging and/or evacuating the process chamber to remove the active species or other elements, without removing the adsorbed layer. The species generated in a plasma can be removed by stopping the plasma and allowing the remaining species to decay, optionally combined with purging and/or evacuation of the chamber. Purging can be done using any inert gas such as N₂, Ar, Ne, He and their combinations. Purging may also be done after any operation, block, or step provided herein, including after a modification operation, after a removal operation, or both. Since the purging is optional, some implementations may not have any purging.

Some implementations vary the process conditions of the modifying and removal operations of blocks 205A and 205B, respectively, such as the duration, temperatures, and pressures of each operation. In some embodiments, blocks 205A and 205B may be performed for substantially the same about of time (e.g., within about 10% or 5% of each other), while in other embodiments they may be performed for different times. For example, block 205A may be performed for a time period shorter or longer than block 205B. The various time periods of each block may range, from about 0.5 seconds to about 500 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

In some implementations, the modification operation of block 205A and the removal operation of block 205B may be performed at different pressures. For example, the modification operation of block 205A may be performed at a first pressure, or first pressure range, and the removal operation of block 205B may be performed at a second pressure, or second pressure range, different than the modification operation of block 205A. Although not depicted in FIG. 2, some implementations may include a pressure adjustment operation that changes the pressure from the first pressure to the second pressure. This pressure adjustment may occur in between blocks 205A and 205B, for example. Similar to above, the first and second pressures may be, for instance, between about 20 millitorr (mTorr) and 760 Torr (1 atm), including between about 20 mTorr and 600 mTorr, about 30 mTorr and 500 mTorr, and about 40 mTorr and 400 mTorr, as well as between about 3 Torr and 8 Torr, and about 4 Torr and 8 Torr, 2 Torr and 10 Torr, and 100 Torr and 760 Torr, for example. In some other embodiments, both the modification operation of block 205A and the removal operation of block 205B may be performed at the substantially same pressure (e.g., within about 10% or 5% of each other), such as any pressure or pressure range described herein.

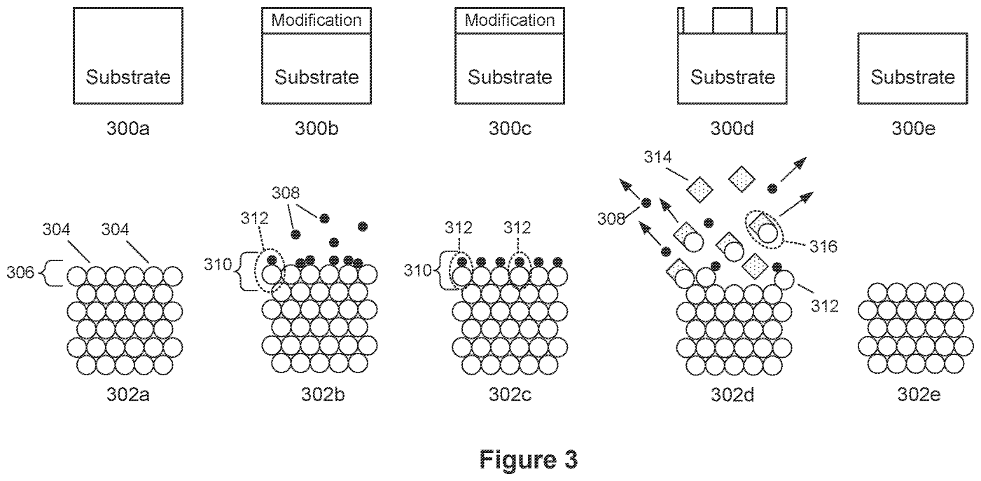

Some implementations of the described etching are further explained with FIG. 3 which depicts an example schematic illustration of atomic layer etching in accordance with disclosed embodiments. Diagrams 300a-300e show an ALE cycle. In 300a, the wafer with one or more layers of chalcogenide is provided. In 300b, the surface of the chalcogenide is modified. In 300c, the next operation is prepared; this preparation may include flowing a second process gas or purging the chamber. In 300d, the wafer is exposed to the removal molecules which react with to the modified chalcogenide layer and cause it to desorb from, and therefore be removed from, the wafer. In 300e, the desired material has been removed.

In diagrams 302a-302e a single layer of chalcogenide material is etched from a wafer. In 302a, the wafer is provided and it has one or more layers of chalcogenide, with each chalcogenide molecule represented as unshaded circles. The top layer of the chalcogenide may be considered a surface layer 306. In 302b, a first process gas with modifying molecules 308 (the solid black circles, some of which are identified with identifier 308) that include a fluoride or chloride is introduced to the wafer which modifies the chalcogenide surface layer 306 to form a fluorinated chalcogenide or a chlorinated chalcogenide. The schematic in 302b shows that some of the modifying molecules 308 are adsorbed onto the chalcogenide molecules 304 of the surface layer 306 to create a modified surface layer 310 that includes modified molecules 312 (one modified molecule 312 is identified inside a dotted ellipse in 302b). As stated above, the modifying molecules 308 may be a species having a fluorine, such as hydrogen fluoride, or a species having a chloride, such as hydrogen chloride. Additionally, the chalcogenide may be any of the materials provided herein, such as GeSbTe or OTS materials. For some thermal ALE techniques, this diagram 302b may occur while the wafer is maintained at the first temperature as described above, e.g., that enables chemisorption of the modifying molecule on the surface of the chalcogenide material. In some other implementations, this modification operation may be plasma assisted.

In diagram 302c, after the modified molecules 312 and the modified surface layer 310 have been created in 302b, the first process gas may be optionally purged from the chamber, as described above and represented in block 207 in FIG. 2.

In diagram 302d, removal molecules 314 are introduced into the process chamber and in some embodiments, this may occur by flowing a second process gas having the second species, i.e., having the removal molecules 314, onto the wafer and the second species may include a compound with a center atom that is aluminum, boron, silicon, or germanium, and with at least one chlorine, such as DMAC. Schematic 302d further illustrates that the removal molecules 314, shown as a shaded diamond, react with the fluorinated chalcogenide or the chlorinated chalcogenide, i.e., the modified molecules 312, which causes the chalcogenide 304 and the fluoride 308 or chloride 308 to desorb from, and thus be removed from, the wafer. In some embodiments, the reaction between the removal molecules 314 and the modified molecules 312 causes the modifying molecules 308 to desorb from the wafer, and causes the removal molecules and the chalcogenide to form another compound 316, illustrated by a combination of the chalcogenide 304 unshaded circle and the removal molecule 314 shaded diamond, which desorbs from the wafer. In some other embodiments, not illustrated, the removal molecules and the modified molecules together form another compound that is caused to desorb from the wafer.

In some thermal ALE embodiments, this removal operation may be performed at a second temperature where desorption of the modified molecules 312 of the modified surface layer 310 from the wafer occurs; no plasma may be utilized in some of these removal operations. In some embodiments, the second temperature is the same, or substantially the same (e.g., within about 10% or 5% of each other), as the first temperature. In other embodiments, the first and second temperatures may be different than each other and, in these embodiments, the temperature may be changed from the first temperature to the second temperature by either heating or cooling the substrate. In some instances, the temperature in one or more of the operations may be ramped up.

In 302e, the modified molecules 312, and therefore the modified surface layer 310, have been removed from the wafer.

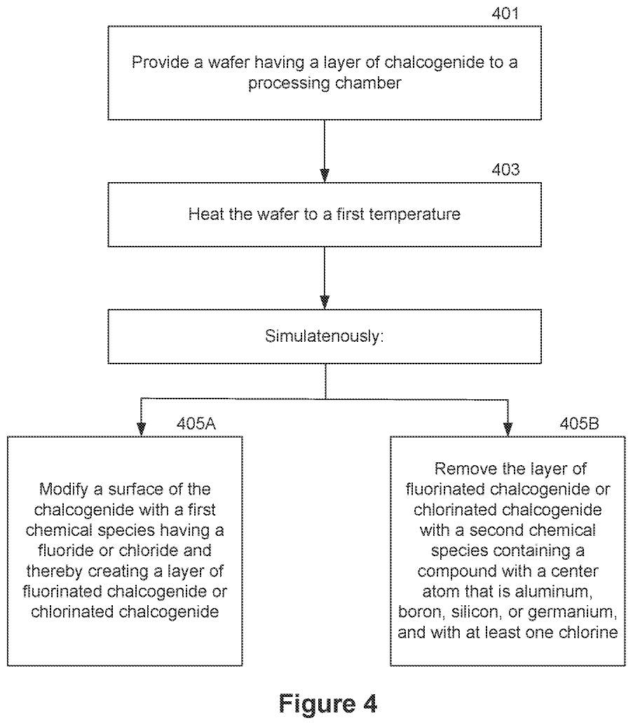

As noted above, some implementations may have at least partially overlapping flows of the modifying species and the removal species, such as overlapping flows of HF and BCl₃, for instance. FIG. 4 depicts a third example process flow diagram for performing operations in accordance with disclosed embodiments. Here, block 401 and 403 are the same as blocks 101 and 103 in FIG. 1. In FIG. 4, at least a portion of the modification and removal operations of block 105 are performed simultaneously as seen with blocks 405A and 405B occurring at the same time. The modification operation of block 405A and the removal operation of block 405B may be the same as described herein above, except for the noted differences, including the timing and overlapping of the first and second species flows onto the wafer. For example, the first species of block 405A has the fluoride or chloride which flows onto the surface of the layer of chalcogenide and modifies the chalcogenide surface to create a modified surface layer, such as the fluorinated chalcogenide or the chlorinated chalcogenide. Additionally, the second species of block 405B has the compound with a center atom that is aluminum, boron, silicon, or germanium, and with at least one chlorine, that reacts with the modified surface layer of the chalcogenide to remove it from the wafer. Other process conditions and implementations are described below. Each process gas may also include a carrier gas as provided above.

In some embodiments, the modification operation of block 405A and the removal operation of block 405B overlap for only some of the etching. In other embodiments, these blocks 405A and 405B overlap for substantially all of the etching (e.g., within about 10% or 5% of each other); some of these implementations have the first and the second chemical species in the same process gas flowed onto the wafer, and some other implementations have these species in separate process gases that are co-flowed or simultaneously flowed onto the wafer.

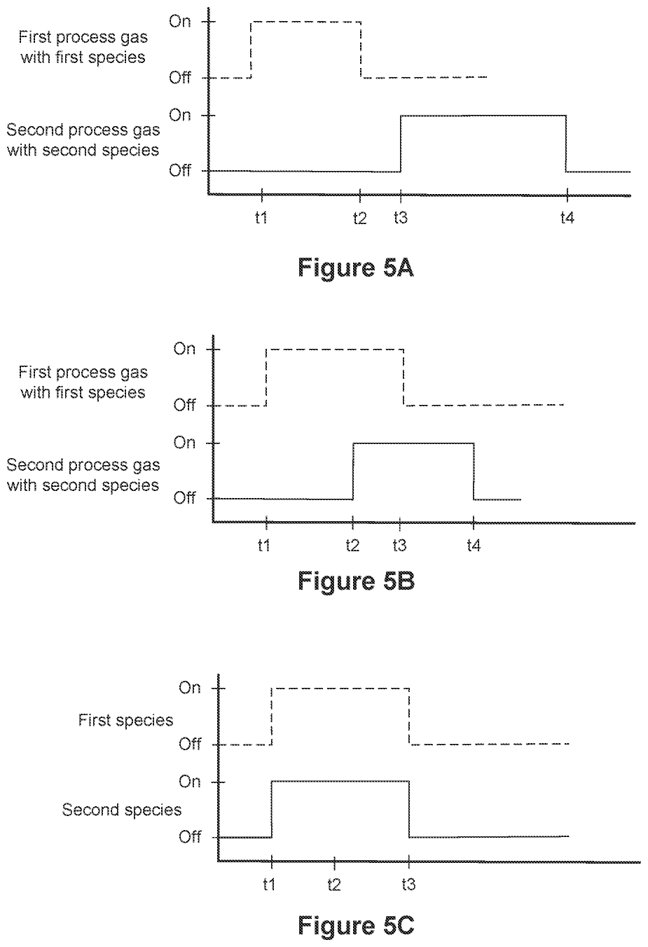

FIGS. 5A through 5C depict example gas flow sequences according to various embodiments. In FIG. 5A, the first process gas with the first species and the second process gas with the second species are flowed onto the wafer without any overlap and may be considered the gas flows described with respect to FIGS. 2 and 3. Here, the first process gas is flowed from time t1 to time t2 after which it is turned off; this may be considered the modification operation of block 205A and schematic 302b. In some instances, the optional purge operation may be performed between time t2 and time t3, such as optional block 207 and schematic 302c. At time t3, the second process gas is flowed onto the wafer until time t4 until it is stopped; this time period may be considered the removal operation of block 205B and schematic 302d.

In FIG. 5B, the first process gas and the second process gas overlap for only a portion of the etching. At time t1, the first process gas is flowed onto the wafer while the second process gas is not flowed onto the wafer, which proceeds until time t2. This may also be considered the modification operation of block 205A and schematic 302b. At time t2, the second process gas is flowed onto the wafer while the first process gas is simultaneously flowed onto the wafer. The first and second process gas both flow onto the wafer between time t2 and time t3; this may be considered the overlapping or co-flowing period of the first and second process gases. Referring back to FIG. 4, this overlapping period may be considered the simultaneous performance of blocks 405A and 405B. At time t3 of FIG. 5B, the first process gas flow is stopped, and the second process gas continues flowing until time t4 when it is stopped. This time may also be considered the removal operation of block 205B and schematic 302d.

In some embodiments, the temperature of the wafer may be adjusted during the etching illustrated in FIG. 5B. For example, the wafer may be maintained at a first temperature between times t1 and t2, adjusted to a second temperature at time t2 and maintained at that second temperature until times t3 or t4. In some such implementations, the temperature may be adjusted to a third temperature at time t3 until time t4. In some other embodiments, the temperature may be held at the first temperature from time t1 to time t3 and then adjusted to the second temperature. This may be considered, in some embodiments, temperature ramp up or ramp down sequence with the second temperature greater than or less than the first temperature, and when applicable, the third temperature greater than or less than the second temperature. These temperatures may be any of those provided herein above. Adjusting the temperatures during any of the etching provided herein may allow for additional control and use of chemisorption and desorption. In some other embodiments, the wafer may be maintained at a substantially constant temperature during the etching of FIG. 5B (e.g., within about 10% or 5% of the set temperature).

Similarly, the wafer temperature may be increased or decreased during the modifying, the removing, or both. Referring to FIG. 5A for instance, the wafer temperature may be increased from a first temperature to a greater second temperature, or decreased from a first temperature to a lower third temperature, during the modifying operation between time t1 and time t2. Alternatively or additionally to this, during the removing operation between time t3 and t4, the wafer temperature may also be increased or decreased.

Alternatively or additionally, the chamber pressure may be adjusted during the etching of FIG. 5B. For example, the chamber may be maintained at a first pressure between times t1 and t2, adjusted to a second pressure at time t2 and maintained at that second pressure until times t3 or t4. In some such implementations, the pressure may be adjusted to a third pressure at time t3 until time t4. In some other embodiments, the pressure may be held at the first pressure from time t1 to time t3 and then adjusted to the second pressure. This may be considered, in some embodiments, pressure ramp up or ramp down sequence with the second pressure greater than or less than the first pressure, and when applicable, the third pressure greater than or less than the second pressure. These pressures may be any of those provided herein above. Adjusting the pressure during any of the etching provided herein may allow for additional control and use of chemisorption and desorption, as well as reducing unwanted residue buildup in the chamber. In some other embodiments, the pressure may be substantially constant during the etching of FIG. 5B (e.g., within about 10% or 5% of the set pressure).

Similarly, the chamber pressure increase or decrease may be performed during the modifying, the removing, or both. Referring to FIG. 5A for instance, the chamber pressure may be increased from a first pressure to a greater second pressure, or decreased from a first pressure to a lower second pressure, during the modifying operation between time t1 and time t2. Alternatively or additionally to this, during the removing operation between time t3 and t, the chamber pressure may also be increased or decreased.

In FIG. 5C, the first species and the second species are co-flowed, or simultaneously flowed, onto the wafer for substantially all of the etching. Due to imperfections in the design, implementation, tolerances, and operation of gas delivery systems, these gases may be intended to be co-flowed for the exactly the same time, but in practice it may not actually be exact. Here in FIG. 5C, the first species and the second species are simultaneously flowed onto the wafer from times t1 to t2 after which they are both stopped. In some implementations, the first and second species may be in the same process gas, along with an optional carrier gas, that is flowed onto the wafer. In some other implementations, the first species may be a part of a first process gas and the second species may be a part of a separate second process gas, as described above, and these first and second process gases are both co-flowed onto the wafer from time t1 to time t2.

In some implementations, it may be advantageous to keep the first and second species separate until they enter the process chamber. This may avoid a cross reaction between the first and second species. The first and second species may therefore be flowed in separate lines and through separate ports into the processing chamber, such as through a dual-plenum showerhead or through separate nozzles, for instance. This may allow the two chemistries to meet only on the wafer surface.

In some embodiments, the temperature of the wafer may be adjusted during the etching illustrated in FIG. 5C and FIG. 4. For example, the wafer may be maintained at a first temperature between times t1 and ta, adjusted to a second temperature at time ta and maintained at that second temperature until time t2. In some such implementations, the temperature may be adjusted to a third temperature or other temperatures throughout this etching. This may be considered, in some embodiments, temperature ramp up or ramp down sequence with, for example, the second temperature greater than or less than the first temperature, and when applicable, the third temperature greater than or less than the second temperature. These temperatures may be any of those provided herein above. In some other embodiments, the wafer may be maintained at a substantially constant temperature during the etching of FIG. 5C.

Alternatively or additionally, the chamber pressure may be adjusted during the etching of FIG. 5C. For example, the chamber may be maintained at a first pressure between times t1 and t2, adjusted to a second pressure at time t2 and maintained at that second pressure until time t3. This may be considered, in some embodiments, pressure ramp up or ramp down sequence with the second pressure greater than or less than the first pressure. These pressures may be any of those provided herein above. In some other embodiments, the pressure may be substantially constant during the etching of FIG. 5C.

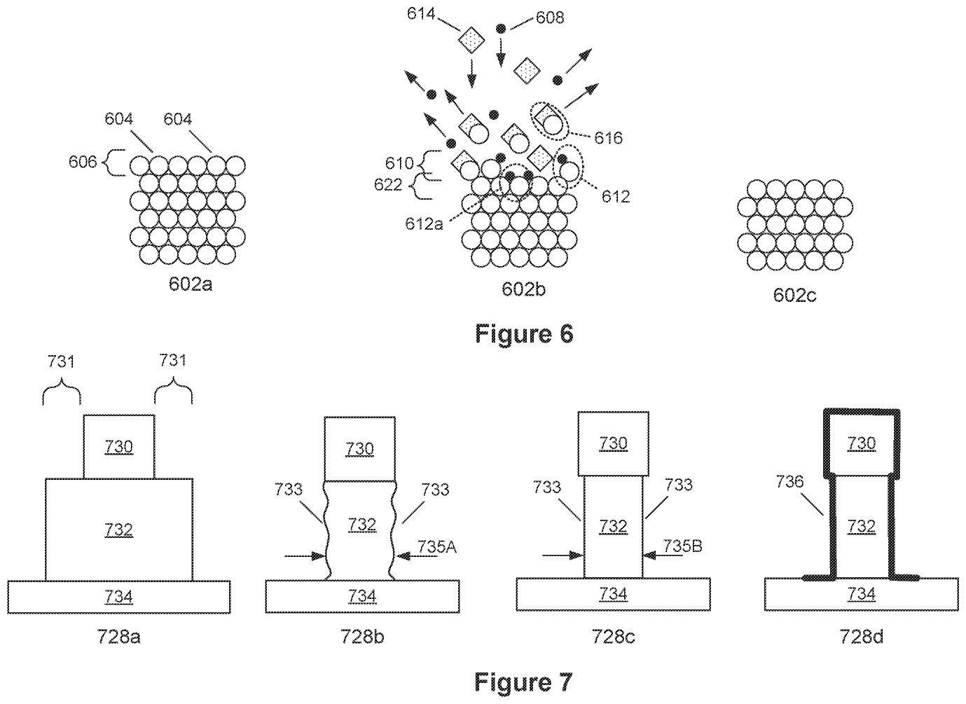

The modification and removal operations with overlapping flows is further illustrated in FIG. 6 which depicts an example schematic illustration of etching in accordance with disclosed embodiments. Diagram 602a corresponds to diagram 302a above in which the wafer is provided and it has one or more layers of chalcogenide, with each chalcogenide molecule represented as unshaded circles. The top layer of the chalcogenide may be considered a surface layer 606. In 602b, the first species, i.e., the modifying molecules 608 (the solid black circles, some of which are identified with identifier 608), and the second species, i.e., the removal molecules 614, are simultaneously introduced into the process chamber; this may represent the co-flows or simultaneous flows described above, such as with respect to FIGS. 4, 5B, and 5C.

Here, some of the modifying molecules 608 are adsorbed onto the chalcogenide molecules 604 of the surface layer 606 to create a modified surface layer 610 that includes modified molecules 612 (one modified molecule 612 is identified inside a dotted ellipse in 602b. As stated above, the modifying molecules 608 may include a fluorine, such as hydrogen fluoride, or a chlorine, such as hydrogen chloride. The removal molecules 614 are also co-flowed onto the wafer and the second species may include compound with a center atom that is aluminum, boron, silicon, or germanium, and with at least one chlorine as provided above. These removal molecules 614 react with the modified molecules 612 and the cause the chalcogenide to desorb from, and thus be removed from, the wafer. In some embodiments, the first species and the second species may be flowed separately into the processing chamber via separate gas lines and/or separate ports (e.g., separate injection nozzles or ports within the same showerhead).

In some embodiments, as the first species and the second species, e.g., the modifying molecules and the removal molecules, are flowed onto the wafer, additional layers of chalcogenide may be etched. For instance, FIG. 602b illustrates that a second layer 622 of the chalcogenide may be similarly modified to form a modified molecule 612a which may also be removed from the wafer when exposed to and reacted with the removal molecules 614.

Diagram 602b may be considered an illustration of etching during simultaneous flows of the first and second species onto the wafer. As described above with respect to FIG. 5B, some modifying may occur before this diagram 602b, which may be represented by diagram 302b. Additionally, in some instances like in FIG. 5B, after this co-flowing of diagram 602b, additional removing may occur without any simultaneous modifying; this may be represented by diagram 302d. In some such embodiments, the etching of FIG. 5B may be illustrated by the sequence of diagram 302b, 602b, and 302d.

Referring back to FIG. 4, the performance of blocks 405A and 405B together for a duration of time may be considered a single ALE cycle. In some implementations, blocks 405A and 405B may be stopped and then repeated in order to perform multiple cycles and remove multiple layers of the chalcogenide. This may include performing, for example, about 1 to 1,000 cycles, about 1 to about 500 cycles, about 1 to about 100 cycles, about 1 cycle to about 30 cycles, or about 1 to about 20 cycles. Any suitable number of ALE cycles may be included to etch a desired amount of chalcogenide film. In some embodiments, ALE is performed in cycles to etch about 1 Angstroms (Å) to about 50 Å of the surface of the layers on the wafer. In some embodiments, cycles of ALE etch between about 2 Å and about 50 Å of the surface of the layers on the wafer. In some embodiments, each ALE cycle may etch at least about 0.1 Å, 0.5 Å, 1 Å, 2 Å, or 3 Å.

In some of the embodiments provided here, the flow rate of the first process gas may remain constant and the flow rate of the second process gas may remain constant. In some other embodiments, the first and second process gases may be flowed at the same or different flow rates. In some other embodiments, it may be advantageous to vary the flow rate of the first and/or the second process gases. This may include, for instance, increasing the second process gas flowrate during the removal operation in order to provide more removal molecules as the removal operation progresses. Some example flow rates may include between about 50 sccm and 1000 sccm.

As provided above, the thermal etching provided herein may be used for various purposes. In some implementations, the thermal etching may be used for the cleaning operations of a chalcogenide after the chalcogenide has been etched using RIE etching or other ion-assisted etching. Additionally or alternatively, some implementations may perform the thermal etching to etch the bulk chalcogenide. In some such instances, the thermal etching may be used instead of the RIE etching or other ion-assisted etching.

Aspects of the thermal etching used as a cleaning operation after another etching process, such as the RIE or other ion-assisted etching, is performed on the chalcogenide will now be discussed. FIG. 7 depicts an example process flow of etching a chalcogenide. In this example, diagram 728a illustrates that the chalcogenide 732 may be deposited as one or more bulk layers on a wafer 734 and a hard mask 730 may be deposited on the chalcogenide 732. An etching process may be performed, such as RIE etching or other plasma-assisted etching, which removes some of the bulk layer (e.g., the areas that extend beyond the hard mask 730 and identified with 731) and forms the desired geometry of the chalcogenide. Here in diagram 728b, the chalcogenide 732 is etched into a pillar. However, as described above, this RIE or plasma-assisted may cause undesirable harm to the chalcogenide, and/or the exposed chalcogenide 732 may become oxidized, and these effects are illustrated with damaged and/or oxidized sidewalls 733.

As noted above, a cleaning operation that utilizes thermal etching, such as thermal ALE, may be performed on the chalcogenide after this RIE or other ion-assisted etching. Diagram 728c illustrates the chalcogenide 732 after the thermal etching cleaning operation has been performed. As shown, at least a part of the damaged and/or oxidized sidewall 733 of the chalcogenide 732 has been removed; this is represented by the chalcogenide 732 having straight sidewalls 733 that has a width 735B narrower than the width 735B in diagram 728b. In some implementations that use thermal ALE, the amount of chalcogenide 732 that is removed can be controlled on a cycle-by-cycle basis and therefore can remove the chalcogenide on a monolayer or sub-monolayer level. One or more cycles of thermal ALE can therefore be performed on the chalcogenide 732 in order to remove the desired amount of chalcogenide. In some embodiments, only some of the damaged and/or oxidized portion of the chalcogenide may be removed by thermal etching because some processing may have an acceptable amount of damaged and/or oxidized chalcogenide that can remain on the wafer. This may improve throughput by performing less etching on the wafer and thereby reducing the wafer's processing time. In some other implementations, substantially all of the damaged and/or oxidized portion of the chalcogenide and in some instances, additional layers of the bulk chalcogenide, may be removed.

Some implementations may further include depositing an encapsulation layer of material after the thermal etching has been performed on the chalcogenide. In some embodiments, as illustrated in diagram 728d of FIG. 7, an encapsulation layer of material 736 may be deposited on the chalcogenide 732 and the mask 730 after the thermal etching clean operations have been performed. The encapsulation material may be deposited using various techniques, such as chemical vapor deposition (“CVD”), plasma-enhanced CVD (“PECVD”), atomic layer deposition (“ALD”), low pressure CVD, ultra-high CVD, physical vapor deposition (“PVD”), and conformal film deposition (“CFD”). Some CVD processes may deposit a film on a wafer surface by flowing one or more gas reactants into a reactor which form film precursors and by-products. The precursors are transported to the wafer surface where they are adsorbed by the wafer, diffused into the wafer, and deposited on the wafer by chemical reactions, including by the generation of a plasma in PECVD. Some other deposition processes involve multiple film deposition cycles, each producing a “discrete” film thickness. ALD is one such film deposition method, but any technique which puts down thin layers of film and used in a repeating sequential matter may be viewed as involving multiple cycles of deposition.

As device and features size continue to shrink in the semiconductor industry, and also as 3D devices structures become more prevalent in integrated circuit (IC) design, the capability of depositing thin conformal films (films of material having a uniform thickness relative to the shape of the underlying structure, even if non-planar) continues to gain importance. ALD is a film forming technique which is well-suited to the deposition of conformal films due to the fact that a single cycle of ALD only deposits a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlying devices structure. In certain embodiments, each ALD cycle includes the following steps: (1) exposure of the substrate surface to a first precursor, (2) purge of the reaction chamber in which the substrate is located, activation of a reaction of the substrate surface, typically with a plasma and/or a second precursor, and purge of the reaction chamber in which the substrate is located.

Depositing a thin film via thermal ALD may include: heating the substrate to an elevated temperature, exposing the substrate to a precursor to adsorb onto a surface of the substrate, and exposing the substrate to one or more gas reactants to drive a surface reaction between the one or more gas reactants and the precursor, thereby forming the thin film via thermal ALD. Specifically, depositing the first silicon oxide layer via thermal ALD includes: heating the substrate to an elevated temperature, exposing the substrate to a silicon-containing precursor to adsorb onto a surface of the substrate, and exposing the substrate to an oxygen-containing reactant to drive a reaction between the oxygen-containing reactant and the silicon-containing precursor, thereby forming the first silicon oxide layer via thermal ALD.

The duration of each ALD cycle may typically be less than 25 seconds or less than 10 seconds or less than 5 seconds. The plasma exposure step (or steps) of the ALD cycle may be of a short duration, such as a duration of 1 second or less, for example. The plasma may be of other durations longer than that 1 second, such as 2 seconds, 5 seconds, or 10 seconds, for instance.

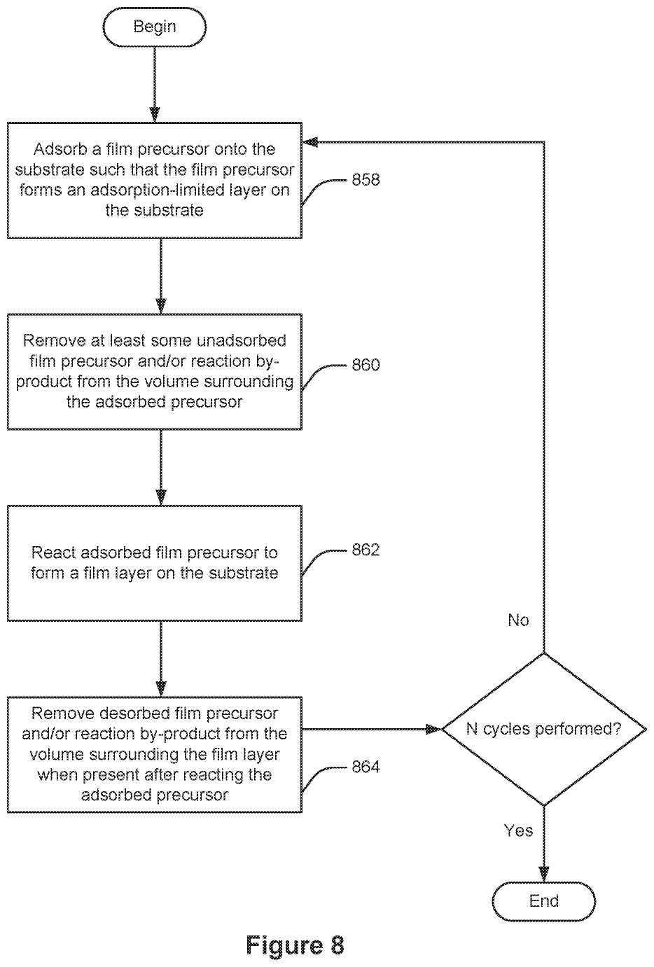

FIG. 8 depicts a flowchart of an example sequence of operations for forming a film of material on a substrate via an ALD process. As can be seen in FIG. 8, item 1 above corresponds with block 858, item 2 above corresponds with block 860, item 3 above corresponds with block 862, and item 4 above corresponds with block 864; the four blocks are performed for N cycles, after which the process is stopped.

In some instances, the encapsulation material may include a silicon, such as a silicon nitride or a silicon oxide. In some implementations, the silicon-containing precursor includes a silane, such as an aminosilane. An aminosilane includes at least one nitrogen atom bonded to a silicon atom, but may also contain hydrogens, oxygens, halogens and carbons. Examples of aminosilanes may include bis(tert-butylamino)silane (BTBAS), N-(diethylaminosilyl)-N-ethylethanamine (SAM-24), tris(dimethylamino)silane (3DMAS), and tetrakis(dimethylamino)silane (4DMAS). In some embodiments, other materials may be deposited for the encapsulation layer. For example, encapsulation layers described herein may include Group IV element nitrides or carbides, any of which may be doped (such as with oxygen) or undoped. In various embodiments, the encapsulation layer may be any of the following chemistries or any of their combinations: silicon nitride (SiN), silicon carbide (SiC), oxygen-doped silicon carbide (SiCO), germanium nitride (GeN), germanium carbide (GeC), and oxygen-doped germanium carbide (GeCO).

In some implementations, operation 862 of FIG. 8 may include flowing a reactant, such as an oxygen-containing reactant can include an oxidant gas such as oxygen (O₂), ozone (O₃), hydrogen peroxide (H₂O₂), water (H₂O), or combinations thereof. In some implementations, exposing the substrate to the oxygen-containing reactant includes flowing hydrogen and oxygen to the substrate to react in situ within the plasma processing chamber to cause an exothermic reaction. In some implementations, it is believed that water may be formed in situ by a reaction between the hydrogen and oxygen. Water vapor may not be flowed into the plasma processing chamber as a starting reactant, but may or may not be formed in situ within the plasma processing chamber. As used herein, flowing “hydrogen” refers to flowing molecular hydrogen and flowing “oxygen” refers to flowing molecular oxygen. The hydrogen and oxygen may be flowed towards the substrate in the plasma processing chamber simultaneously. The exothermic reaction involving hydrogen and oxygen may release energy for driving a surface reaction with the adsorbed silicon-containing precursor to form the first silicon oxide layer.

During an ALD cycle of FIG. 8, the wafer may be exposed to the oxygen-containing reactant and exposed to an elevated temperature for a suitable duration during the cycle, such as during thermal oxidation of operation 862. The duration of operation 862 may be between about 0.1 seconds and about 6 seconds, between about 0.2 seconds and about 4 seconds, or between about 0.5 seconds and about 3 seconds. The substrate may be operating at the elevated temperature simultaneously with exposing the substrate to the oxygen-containing reactant. In some implementations, the elevated temperature may be between about 150° C. and about 750° C., between about 150° C. and about 500° C., between about 500° C. and about 650° C., or between about 550° C. and about 650° C. The substrate may be exposed to increased chamber pressure during one or more of these operations of FIG. 8, such as equal to or greater than about 7 Torr, equal to or greater than about 10 Torr, equal to or greater than about 12 Torr, or between about 10 Torr and about 20 Torr.

In some ALD processes that use a plasma to react the adsorbed precursor, the chamber pressure in the plasma processing chamber may be relatively low and between about 10 mTorr and about 200 mTorr, or may be relatively high and between about 1 Torr and about 7 Torr. An RF field is applied to the plasma processing chamber to generate ions and radicals of the oxygen-containing reactant. In various implementations, the RF frequency used to generate the plasma may be at least about 13.56 MHz, at least about 27 MHz, at least about 40 MHz, or at least about 60 MHz, though other frequencies may also be used. In some implementations, the RF power may be a few hundred Watts, for example about 500 W or less, about 400 W or less, or about 300 W or less, though it will be understood that other RF powers may be applied depending on substrate area. In some implementations, the duration of the plasma exposure phase may be between about 0.1 seconds and about 120 seconds or between about 1 second and about 60 seconds.

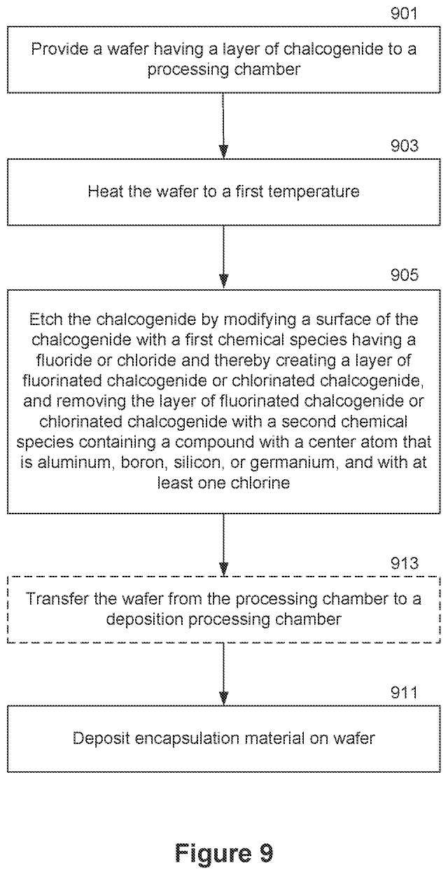

Additional etching techniques of a chalcogenide that may be used for cleaning operations after an RIE etching or other ion-assisted etching, as well as for etching the bulk chalcogenide material will now be discussed. FIG. 9 depicts a third example process flow diagram for performing operations in accordance with disclosed embodiments. Blocks 901, 903, and 905 are the same as blocks 101, 103, and 105, respectively of FIG. 1 described above. The operation of block 901 through 905 may be performed after an RIE etching or other ion-assisted etching, and to etch one or more layers of the bulk chalcogenide material instead of the RIE or other ion-assisted etching. It will be understood that the etching of block 905 may be performed in any manner provided herein, including as two shown in FIG. 2 with separate modification and removal operations separated with a purge operation. The etching of block 905 may also represent the cleaning operation by thermal etching provided above. Here in FIG. 9, an encapsulation material is deposited on the wafer in block 911 after thermal etching is performed on the wafer. This encapsulation may be performed in any manner provided herein, including by ALD, and the material may include a silicon, such as a silicon nitride or silicon oxide.

In some embodiments, the etching operations, including the thermal etching and thermal ALE, may be performed in one or more etching chambers while the encapsulation deposition is performed in another processing chamber, such as a deposition chamber that is configured to deposit material on a wafer. The wafer may therefore be transferred from the one or more etching chambers to the deposition processing chamber, as represented by optional block 913 in FIG. 9. In some embodiments, the wafer may be transferred between chambers while the wafer and the chambers, including transferred chambers, are maintained at a vacuum or low pressure, e.g., between about 1 mTorr and about 10 Torr, such that the wafer is not exposed to atmospheric pressure during this transfer.

For example, the one or more etching chambers and the deposition chamber may be maintained at a vacuum or other low pressure and the wafer may be transferred from the one or more etching chambers to the deposition chamber through one or more transfer chambers that are also maintained at vacuum or other low pressure. During this transfer, the wafer and the etched chalcogenide are not exposed to atmospheric pressure. Transferring the wafer in such a manner advantageously reduces the time that the etched chalcogenide is exposed to air, oxygen, or other environmental gases, thereby reducing or preventing unwanted oxidation of the chalcogenide; this transferring also advantageously increases throughput of the processed wafer by eliminating pump down steps and additional transfers that are performed when a wafer is transferred between vacuum and atmospheric pressures.

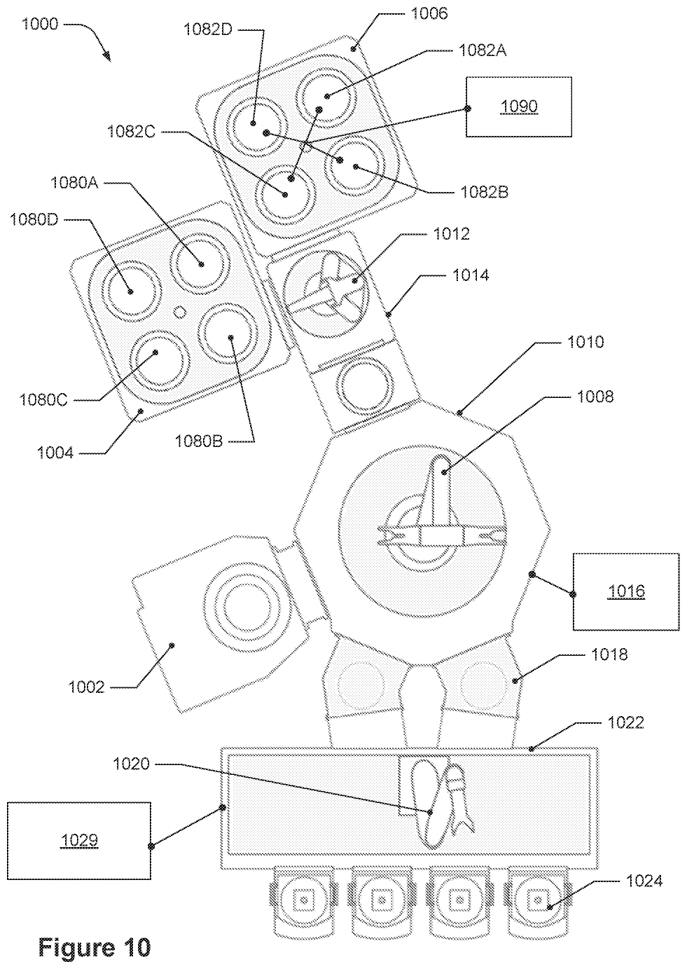

Transferring the wafer is further explained with FIG. 10 which depicts a first example processing apparatus according to disclosed embodiments. Additional features of tool 1000 will be discussed in greater detail below, and various features are discussed here with respect to some of the described techniques. Tool 1000 includes a first processing chamber 1002, a second processing chamber 1004, and a third processing chamber 1006. In some implementations, the first processing chamber 1002 is configured to perform etching operations on a wafer, including etching of the bulk chalcogenide, such as RIE or other ion-assisted etching, and the second processing chamber 1004 is configured to perform thermal etching, including thermal ALE. The second processing chamber 1004 also includes a plurality of processing stations, four stations 1080A-D, that each may process a wafer. The first and second processing chambers 1002 and 1004 may be considered etching chambers. The third processing chamber 1006 is configured to perform deposition on the wafer and may be considered a deposition chamber. The third processing chamber 1006 also includes a plurality of processing stations, four stations 1082A-D, that each may process a wafer. The second and third processing chambers 1004 and 1006 may be considered multi-station processing chambers.

The tool 1000 also includes a wafer transfer unit is configured to transport one or more wafers within the tool 1000. For example, after a wafer has been etched in the first processing chamber 1002, the wafer transfer unit is able to transfer the wafer from the first processing chamber 1002, to the second processing chamber 1004 where thermal etching described herein may be performed on one or more wafers. Following this thermal etching in the second processing chamber 1004, the wafer transfer unit may transfer one or more wafers from the second processing chamber 1004 to the third processing chamber 1006 where one or more layers of encapsulation material may be deposited on one or more wafers.

In the depicted illustration of FIG. 10, the wafer transfer unit includes a first robotic arm unit 1008 in a first wafer transfer module 1010 and a second robotic arm unit 1012 in a second wafer transfer module 1014. The first robotic arm unit 1008 is configured to transport a wafer between the first processing chamber 1002 and the second robotic arm unit 1012, and the second robotic arm unit 1012 is configured to transport the wafer between the first robotic arm unit 1008, the second processing chamber 1004, and the third processing chamber 1006. In one implementation, each robotic arm unit 1008 and 1012 may have one arm, and in another implementation, they may each have two arms, where each arm has an end effector 1224 to pick substrates for transport. Front-end robot 1020, in atmospheric transfer module (ATM) 1022, e.g., equipment front end module (EFEM), may be used to transfer substrates from a cassette or Front Opening Unified Pod (FOUP) 1024 to airlock 1018.

The first and second wafer transfer modules may each be a vacuum transfer module (VTM). Airlock 1018, also known as a loadlock or transfer module, is shown and may be individually optimized to perform various fabrication processes. The tool 1000 also includes a pressure unit 1016 that is configured to lower the pressure of the tool 1000 to a vacuum or low pressure, e.g., between about 1 mTorr and about 10 Torr, and maintain the tool 1000 at this pressure. This includes maintaining the first, second and third processing chambers 1002-1006, the first wafer transfer module 1010, and the second wafer transfer module 1012 at the vacuum or low pressure.

As the wafer is transferred throughout the tool, it is able to be within an environment that is maintained at the vacuum or low pressure. For example, as the wafer is transferred from the first processing chamber 1002, into the first wafer transfer module 1010, to the second wafer transfer module 1014, to the second processing chamber 1004, the wafer is exposed to and maintained at the vacuum or low pressure, and therefore not exposed to atmospheric pressure. Similarly, as the wafer is transferred from the second processing module 1004, to the second wafer transfer module 1014, and to the third processing module 1006, the wafer is maintained at the vacuum or low pressure and not exposed to atmospheric pressure.

In a further example, a substrate is placed in one of the FOUPs 1024 and the front-end robot 1020 transfers the substrate from the FOUP 1024 to an aligner, which allows the substrate to be properly centered before it is etched, or deposited upon, or otherwise processed. After being aligned, the substrate is moved by the front-end robot 1020 into an airlock 1018. Because airlock modules have the ability to match the environment between an ATM and a VTM, the substrate is able to move between the two pressure environments without being damaged. From the airlock module 1018, the substrate is moved by the first robot arm unit 1008 through the first wafer transfer module 1010, or VTM 1010, and into the first processing chamber 1002. In order to achieve this substrate movement, the first robot arm unit 1008 uses end effectors on each of its arms.

In some of the implementations that use the tool 1000 of FIG. 10, etching operations may be performed in more than one processing chamber. For example, etching operations may be performed in processing chamber 1002, such as RIE or other ion-assisted etching, while thermal etching, such as thermal ALE, may be performed in a different processing chamber, such as the second processing chamber 1004. Using two different etching processing chambers may enable the use of different etching techniques on the wafer. For instance, etching of the bulk chalcogenide may be performed in the first processing chamber 1002 and the thermal etching cleaning operations may be performed in the second processing chamber 1004.

In some embodiments, instead of using the RIE etching or other ion-assisted etching to remove the chalcogenide, thermal etching may be used to etch the bulk chalcogenide. The techniques for thermal etching of the bulk chalcogenide may be the same as provided above, such as in FIGS. 1-6, 8, and 9, except that cleaning operations may be unnecessary because no RIE or ion-assisted etching is performed. For example, referring back to FIG. 9, block 901 may include providing the wafer to a processing chamber configured for thermal etching, such as thermal ALE. Blocks 903 and 905 may then be performed in order to etch the bulk chalcogenide, which may include performing multiple thermal ALE cycles as described above and illustrated in FIGS. 1-6. Following the thermal etching of block 905, the wafer may be transferred to a deposition chamber in block 913 where an encapsulation material is deposited thereon in block 911.

In order to etch the bulk chalcogenide as well as to etch some of the damaged and/or oxidized chalcogenide, some of the thermal etching provided herein may include etching multiple layers, such as concurrently etching the multiple layers of chalcogenide. This may include multiple layers of chalcogenide located within stacks of material. For example, the wafer may have a plurality of trenches, holes, or vias that each have sidewalls with multiple layers of material and differing geometries. In order to form various devices, a chalcogenide material may be deposited into these trenches, holes, or vias and with the isotropic nature of the thermal etching described herein, the chalcogenide material can be etched within the various structures.

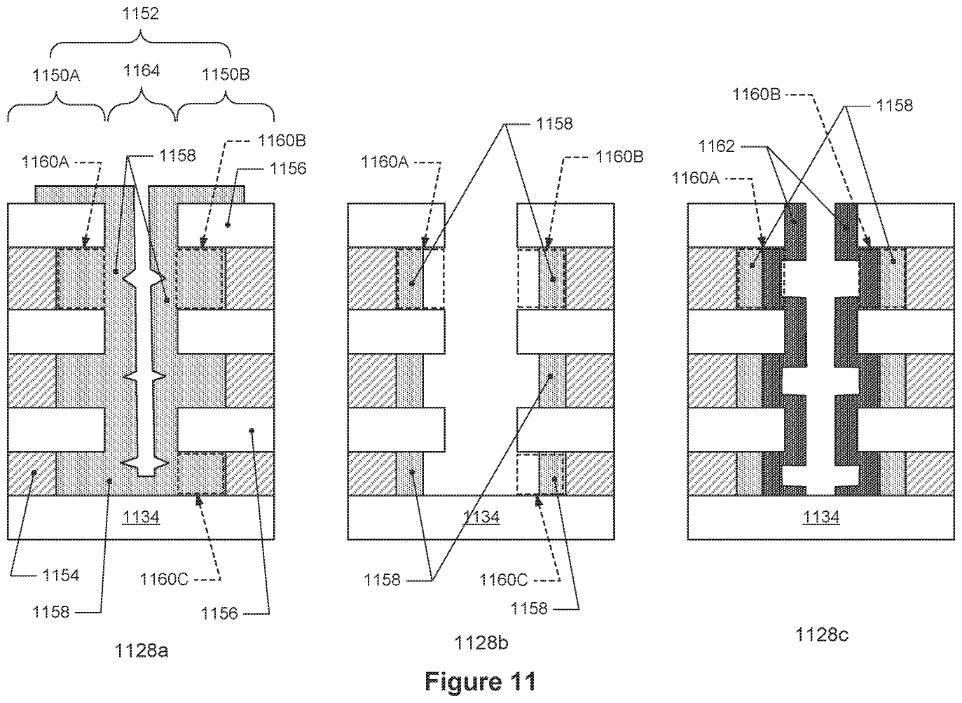

Etching multiple layers of chalcogenide material is illustrated in FIG. 11 which depicts yet another example process flow of etching layers of a chalcogenide. Here, a partial cross-sectional view of one feature 1152 of a wafer 1134 is shown and the feature may be a trench, hole, or via, for instance. Each side wall 1150A and 1150B of the feature 1152 includes a plurality of materials, such as a metal 1154 (shown with cross-hatching) and a dielectric 1156. A layer of chalcogenide material 1158 (shown with shading) is deposited within the feature 1152 and onto a surface of the materials 1154 and 1156 of the sidewalls 1150A and 1150B.

Thermal etching of the bulk chalcogenide material 1158 may be performed in order to remove multiple layers of the chalcogenide material 1158, which includes concurrently etching multiple layers of this chalcogenide material 1158. Because the thermal etching is isotropic and non-directional, the thermal etching of the chalcogenide material 1158 is able to etch within each area, overhang, recess, and other geometric area of the feature 1152. In diagram 1128a, the thermal etching may remove multiple layers of the chalcogenide 1158 within the gap 1164 of the feature 1152 which may include layers of the bulk, monolithic chalcogenide 1158. Once the chalcogenide 1158 has been removed from the gap 1164, the chalcogenide may be present as discrete, separate portions of material within the various areas of the feature. For instance, in diagram 1128a, areas 1160A, 1160B, and 1160C that are encompassed within the dotted squares, have discrete portions of chalcogenide 1158 therein; directional etching, such as RIE etching, is unable to etch the chalcogenide within these areas. However, the thermal etching techniques are able to reach and etch each layer of the chalcogenide 1158 in these areas concurrently. In Figure diagram 1128b, the chalcogenide 1158 has been etched back in each of the areas, including etching multiple layers concurrently. In some instances, each portion of the chalcogenide 1158 in each area may be considered a layer of the chalcogenide 1158.

Similar to above, after the chalcogenide material 1158 has been etched, an encapsulation material 1162 (shown with dark shading) is deposited thereon with ALD as illustrated in diagram 1128c. Because ALD is a conformal deposition, the encapsulation material 1162 is able to be deposited on the various geometries in the feature 1152.

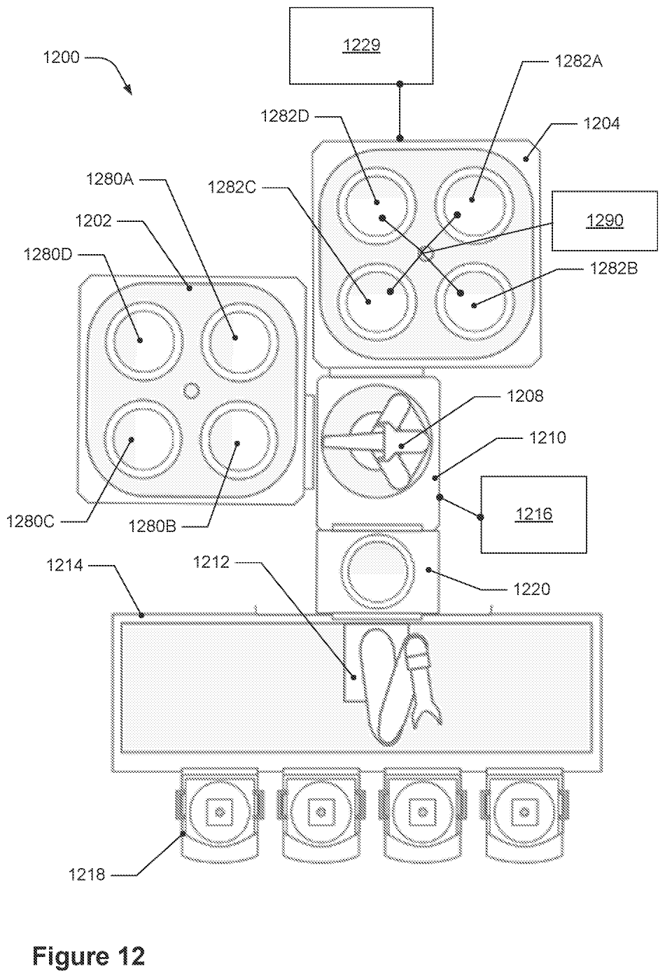

Various apparatuses may be used to perform thermal etching of the bulk chalcogenide. For example, in tool 1000 of FIG. 10, the second processing chamber 1004 may be used for this thermal etching and the third processing chamber 1006 may be used for depositing the encapsulation material. In another example, an apparatus with two processing chambers may be used. FIG. 12 depicts a second example processing apparatus according to disclosed embodiments. Tool 1200 includes a first processing chamber 1202 and a second processing chamber 1204. This tool 1200 does not include the first processing chamber 1000 of FIG. 10. The first processing chamber 1202 includes a plurality of processing stations, four stations 1280A-D, that each may process a wafer. The first processing chamber 1202 is configured to perform thermal etching operations on the wafers, including thermal etching, such as thermal ALE, of the bulk chalcogenide material. The second processing chamber 1204 is configured to perform deposition on the wafer and may be considered a deposition chamber. The second processing chamber 1204 also includes a plurality of processing stations, four stations 1282A-D, that each may process a wafer. The first and second processing chambers 1202 and 1204 may be considered multi-station processing chambers. Processing chambers 1202 and 1204 may be, in some embodiments, the same as the processing chambers 1004 and 1006 of FIG. 10.

Tool 1200 also includes a wafer transfer unit configured to transport one or more wafers within the tool 1200. Additional features of tool 1200 will be discussed in greater detail below, and various features are discussed here with respect to some of the described techniques. In the depicted illustration, the wafer transfer unit includes a first robotic arm unit 1208 in a first wafer transfer module 1210 and a second robotic arm unit 1212 in a second wafer transfer module 1214 that may be considered an equipment front end module (EFEM) configured to received containers for wafers, such as a front opening unified module (FOUP) 1216. The first robotic arm unit 1208 is configured to transport a wafer between the first processing chamber 1202 and the second processing chamber 1204, and between the second the second robotic arm unit 1212. The second robotic arm unit 1212 is configured to transport the wafer between a FOUP and the first robotic arm unit 1208. After a wafer has been etched using thermal etching, such as thermal ALE, in the first processing chamber 1202, the wafer transfer unit is able to transfer the wafer from the first processing chamber 1202, to the second processing chamber 1204 where one or more layers of encapsulation material may be deposited on one or more wafers.

Similar to above, the first transfer module 1210 may a vacuum transfer module (VTM). Airlock 1220, also known as a loadlock or transfer module, is shown and may be individually optimized to perform various fabrication processes. The tool 1200 also includes a pressure unit 1216 that is configured to lower the pressure of the tool 1200 to a vacuum or low pressure, e.g., between about 1 mTorr and about 10 Torr, and maintain the tool 1200 at this pressure. This includes maintaining the first and second processing chambers 1202 and 1204, and the first wafer transfer module 1210 at the vacuum or low pressure. The second wafer transfer module 1214 may be at a different pressure, such as atmospheric. As the wafer is transferred throughout the tool 1200, it is therefore maintained at the vacuum or low pressure. For example, as the wafer is transferred from the first processing chamber 1202, into the first wafer transfer module 1210, and to the second processing chamber 1204, the wafer is maintained at the vacuum or low pressure and not exposed to atmospheric pressure.

In a further example, a substrate is placed in one of the FOUPs 1218 and the second robot arm unit 1212, or front-end robot, transfers the substrate from the FOUP 1218 to an aligner, which allows the substrate to be properly centered before it is etched, or deposited upon, or otherwise processed. After being aligned, the substrate is moved by the front-end robot 1212 into the airlock 1220. Because airlock modules have the ability to match the environment between an ATM and a VTM, the substrate is able to move between the two pressure environments without being damaged. From the airlock module 1220, the substrate is moved by the first robot arm unit 1208 through the first wafer transfer module 1210, or VTM 1210, and into the first processing chamber 1202. In order to achieve this substrate movement, the first robot arm unit 1208 uses end effectors on each of its arms.

Deposition of the encapsulation material may be performed in different manners, some of which are now described. Referring back to FIG. 9 for instance, the encapsulation material may be deposited on the wafer per block 911 while the wafer is in the deposition chamber, such as the third processing chamber 1006 of tool 1000 or the second processing chamber 1204 of tool 1200. In some implementations, before this encapsulation material is deposited, another encapsulation material may be deposited on the wafer while it is in the thermal etching chamber, such as the second processing chamber 1004 of tool 1000 or the first processing chamber 1202 of tool 1200.

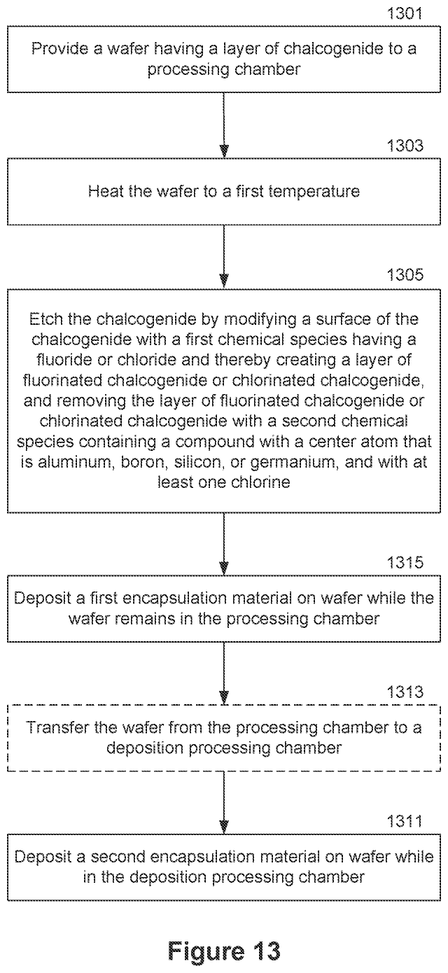

FIG. 13 depicts another technique in accordance with disclosed embodiments. Here, block 1301, 1303, and 1305 are the same as blocks 901, 903, and 905 in FIG. 9, and as blocks 101, 103, and 105 in FIG. 1. It will be understood that the etching of block 1305 may be performed in any manner provided herein, including as two shown in FIG. 2 with separate modification and removal operations separated with a purge operation. The etching of block 1305 may also represent the cleaning operation by thermal etching provided above.

In block 1315, a first encapsulation material is deposited on the wafer after the thermal etching and while the wafer remains in the etching chamber. This deposition may use one of the first or second chemical species used in the etching, along with one or more additional constituents in order to deposit the first encapsulation material. In some implementations, at least some of the process conditions may remain the same as those used in the etching, such as temperature of the wafer or pressure in the processing chamber. Some implementations may deposit a first encapsulation material that include an aluminum which may offer good protection of the underlying chalcogenide, such as GST. The first encapsulation material include, for instance, an aluminum oxide or an aluminum fluoride.

In one example, the etching of operation 1305 may include a second chemical species that includes DMAC. The deposition in operation 1315 may flow the second species having DMAC, and flow a third chemical species, such as water vapor, onto the wafer to deposit aluminum oxide. The water vapor and processing conditions cause the DMAC to be converted to aluminum oxide and further cause the aluminum oxide to be deposited via ALD onto the wafer. In another example, the second species may have TMA which is flowed onto the wafer with third chemical species, such as water vapor, onto the wafer to deposit aluminum oxide. The water vapor again converts the TMA to an aluminum oxide which is deposited via ALD onto the wafer. The activation energy for the deposition is provided by the thermal energy of wafer and processing chamber, not with a plasma. ALD deposition using thermal energy, not a plasma, may be considered thermal ALD. Accordingly, some implementations of block 1315 use thermal ALD to deposit the first encapsulation material.

After the deposition of the first encapsulation material in the chamber in which etching was performed, blocks 1313 and 1311 may be performed to transfer the wafer to the deposition processing chamber and perform further deposition therein.

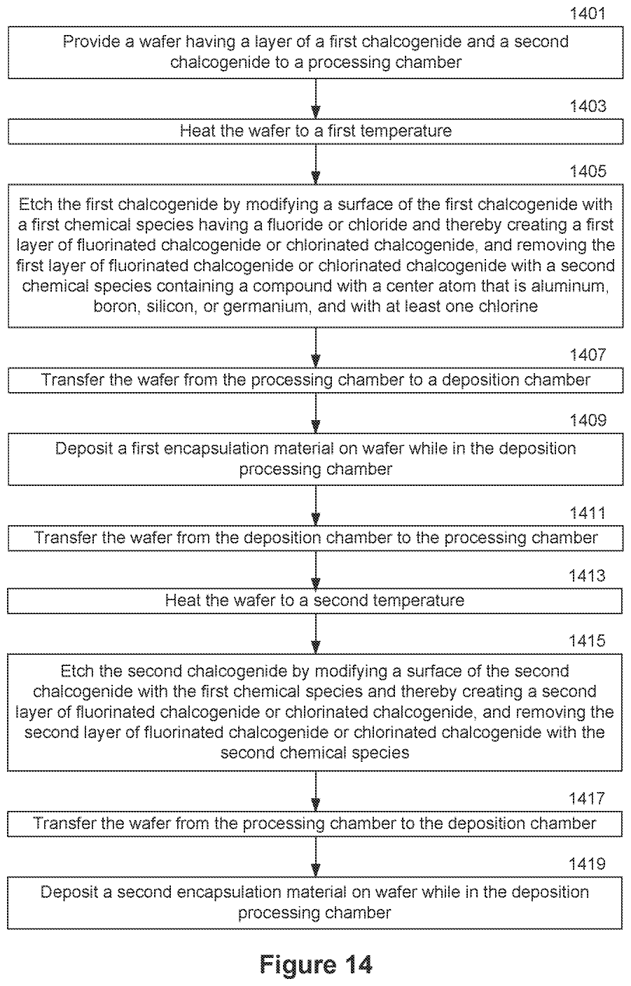

In some embodiments, two different chalcogenides may be etched on the wafer. FIG. 14 depicts yet another technique in accordance with disclosed embodiments. In block 1401, the wafer provided to the processing chamber has two different chalcogenides and once in the chamber, the wafer is heated to the first temperature in block 1403 as described above with respect to block 103 of FIG. 1. In block 1405 the first chalcogenide is etched as described herein, including by modifying a surface of the first chalcogenide with a first chemical species having a fluoride or chloride and thereby creating a first layer of fluorinated chalcogenide or chlorinated chalcogenide, and removing the first layer of fluorinated chalcogenide or chlorinated chalcogenide with a second chemical species containing a compound with a center atom that is aluminum, boron, silicon, or germanium, and with at least one chlorine. It will be understood that the etching of block 1405 may be performed in any manner provided herein, including as two shown in FIG. 2 with separate modification and removal operations separated with a purge operation, as well as with multiple cycles of removal. The etching of block 1405 may also represent the cleaning operation by thermal etching provided above.

After the etching of the block 1405, the wafer is transferred from the processing chamber to a deposition chamber in block 1407. This transferring may be the same as described above, such as with respect to block 913 of FIG. 9 and illustrated in FIG. 10. Once in the deposition chamber, in block 1409 the first encapsulation material is deposited onto the wafer while it is in the deposition chamber, similar to described above, such as with respect to block 911 of FIG. 9.

After this deposition, the wafer may be transferred back to the processing chamber for further etching, as provided in block 1411. In some other embodiments, the wafer may be transferred to one or more other processing chambers for different processing, after which the wafer may be transferred to the processing chamber for etching. Once in the processing chamber, or etching chamber, the wafer is heated to the first temperature in block 1413, similar to block 1403, and the second layer chalcogenide is etched as provided in block 1415. In some embodiments, other RIE or other ion-assisted etching may be performed and the etching in block 1415 may be cleaning operations, while in other embodiments, the etching may be etching the bulk chalcogenide material.

The etching of block 1415 includes modifying a surface of the second chalcogenide with a first chemical species having a fluoride or chloride and thereby creating a first layer of fluorinated chalcogenide or chlorinated chalcogenide, and removing the second layer of fluorinated chalcogenide or chlorinated chalcogenide with a second chemical species containing a compound with a center atom that is aluminum, boron, silicon, or germanium, and with at least one chlorine. It will be understood that the etching of block 1415 may be performed in any manner provided herein, including as two shown in FIG. 2 with separate modification and removal operations separated with a purge operation, as well as with multiple cycles of removal. The etching of block 1415 may also represent the cleaning operation by thermal etching provided above.

In some embodiments, the first temperature, the first chemical species, and the second chemical species may be used to etch both the first chalcogenide material and the second chalcogenide material. In some other embodiments, one or more of these items may be different for etching the first and second chalcogenides. For example, the first species used for etching the first chalcogenide may include a fluorine while the first species used for etching the second chalcogenide may include a chlorine. In another example, the second species used for etching the first chalcogenide may include DMAC while the second species used for etching the second chalcogenide may include TMA.

After block 1415, the wafer may again be transferred from the processing chamber to the deposition chamber in block 1417 for another deposition of a second encapsulation material onto the wafer in block 1419. The encapsulation deposition may be the same as provided herein. In some embodiments, the encapsulation material deposited onto the first chalcogenide and the second chalcogenide may be the same, while in other embodiments they may differ.

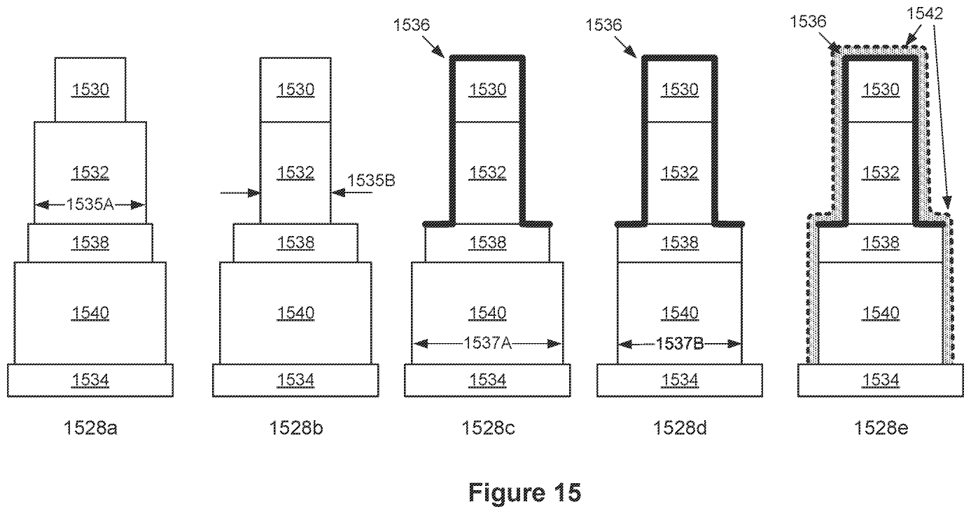

The technique of FIG. 14 is further illustrated with FIG. 15 which depicts an example process flow of etching two chalcogenides. In this example, diagram 1528a includes a wafer 1534 having a stack of materials that includes a hard mask 1530 deposited on a first chalcogenide 1532, which is deposited on another layer of material 1538, which may be another mask, followed by a second chalcogenide 1540. This diagram 1528a and FIG. 15 is an illustration of the concepts herein and not intended to include all the layers of a stack of materials. Diagram 1528a may correspond with block 1401 of FIG. 14. In diagram 1528b, the first chalcogenide 1532 has been etched and this diagram may correspond with blocks 1403 and 1405 of FIG. 14. The etching is also illustrated as a reduction of the width 1535A of the first chalcogenide material 1532 between diagram 1528a and 1528b where the width 1535B is smaller. Following this etching of the first chalcogenide material 1532, a layer of first encapsulation material 1536 is deposited on the hard mask 1530 and the first chalcogenide 1532, as described with respect to block 1409.

After this first encapsulation material 1536 is deposited, another etching process may be performed which etches the second chalcogenide 1540 as shown in diagram 1528d and described above with respect to blocks 1413 and 1415. The etching is also illustrated as a reduction of the width 1527A of the second chalcogenide material 1540 between diagram 1528c and 1528d where the width 1527B is smaller. A second encapsulation layer 1542 is then deposited on the etched second chalcogenide material 1540 and in some instances, as illustrated in diagram 1528e, on the first encapsulation material 1536. The second encapsulation material 1442 is depicted with shading having a dotted boundary line. Diagram 1528e corresponds with block 1419 of FIG. 14.

The techniques and apparatuses described herein provide numerous benefits and advantages. For example, using thermal etching to perform cleaning operations after RIE etching or other ion-based etching allows the wet cleaning operations to be omitted which provides numerous benefits. Some such benefits include not having the wafer transferred from a vacuum environment, to atmosphere for the wet cleaning, and back to the vacuum environment thereby retaining the wafer at vacuum, preventing or reducing unwanted oxidization of the chalcogenide, and improving wafer throughput by decreasing processing time. Further, the liquid delivery system for the wet cleaning operations is not needed for the apparatus which reduces the tool's footprint, reduces maintenance of the system, and reduces costs by not requiring such system and liquids. Additional benefits also include reducing or eliminating damage that may be caused to the chalcogenide and wafer by the wet cleaning operations, such as structure collapse from the liquid surface tension, and no surface modification reactants are needed.

The thermal techniques provided herein may also enable etching on a monolayer or sub-monolayer scale to remove precise amounts of chalcogenide and therefore provide uniform etching. As described above, because these thermal etching techniques are isotropic, complex geometries may be etched without requiring a line of sight or directional etching.

The apparatuses provided herein also reduce complexity and increase wafer throughput by being able to process wafers, including etching and depositing encapsulation material in multi-station chambers.

### Additional Apparatuses

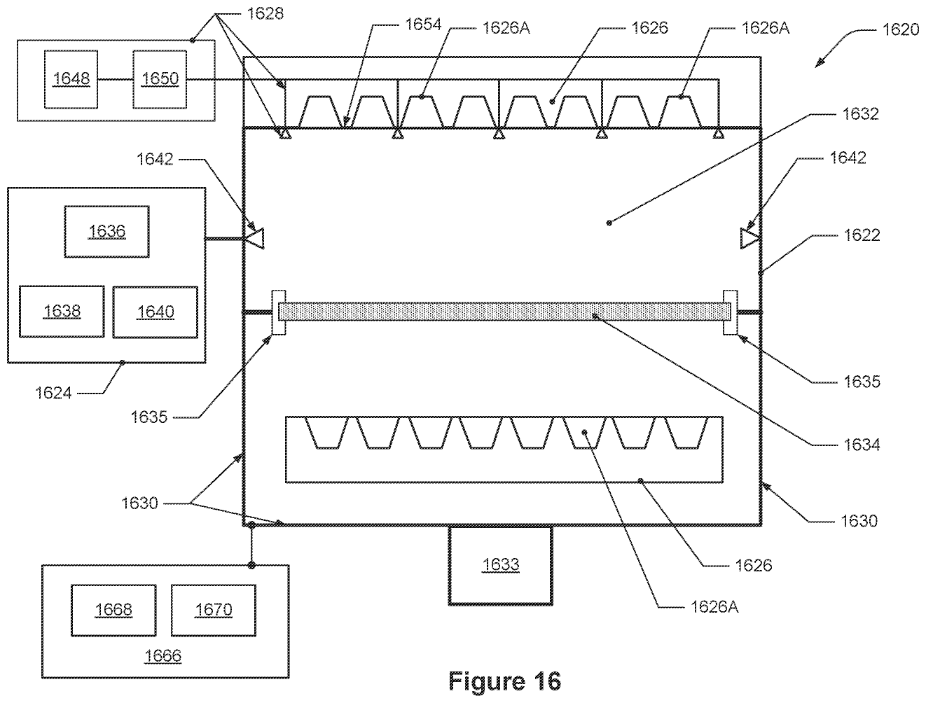

The present disclosure includes the apparatuses provided above and herein below. Referring now to FIG. 16, an example of a substrate processing chamber for etching materials according to the present disclosure is shown. While a specific substrate processing chamber is shown and described, the methods described herein may be implemented on other types of substrate processing systems. FIG. 16 depicts an example apparatus 1620 for semiconductor processing in accordance with disclosed embodiments, including thermal atomic layer etching; this apparatus 1620 includes a processing chamber 1622, a process gas unit 1624, a substrate heating unit 1626, and a substrate cooling unit 1628. The processing chamber 1622 has chamber walls 1630 that at least partially bound and define a chamber interior 1632 (which may be considered a plenum volume).

The process gas unit 1624 is configured to flow process gases, which may include liquids and/or gases, such as a reactant, modifying molecules, converting molecules, or removal molecules, onto a substrate 1634 in the chamber interior 1632. The process gas unit 1624 also includes one or more flow features 1642 configured to flow the first process gas onto the substrate 1634, such as a hole, a nozzle (two of which are depicted), or a showerhead. The one or more flow features 1642 may be positioned above, below, on the side, or a combination of positions, within the chamber interior 1632, such as on the processing chamber walls, top, and bottom, for instance. The process gas unit 1624 may include a mixing vessel for blending and/or conditioning process gases for delivery to the chamber interior 1632. One or more mixing vessel inlet valves may control introduction of process gases to the mixing vessel.

The process gas unit 1624 may include a first process gas source 1636, a first process liquid source 1638, a vaporization point (not depicted) which may vaporize the first liquid into a gas, and a carrier gas source 1640. Some reactants may be stored in liquid form prior to vaporization and subsequent to delivery to the process chamber 1622. The first process gas may comprise a chlorine or a fluorine configured to modify one or more layers of material on the substrate, without using a plasma, in some embodiments; the second process gas may comprise a compound with a center atom that is aluminum, boron, silicon, or germanium, and with at least one chlorine, onto the wafer in the second processing chamber as described above.

In some implementations, the vaporization point may be a heated liquid injection module. In some other implementations, the vaporization point may be a heated vaporizer. In some other embodiments, the vapor may be generated by drawing a vacuum above a container containing the liquid reagent. In yet other implementations, the vaporization point may be eliminated from the process station. In some implementations, a liquid flow controller (LFC) upstream of the vaporization point may be provided for controlling a mass flow of liquid for vaporization and delivery to the chamber interior 1632. The carrier gas source 1640 includes one or more carrier gases or liquids that may be flowed with the processing gas; these may be inert gases like N₂, Ar, Ne, He. The apparatus 1620 may also include a vacuum pump 1633 configured to pump the chamber interior to low pressures, such as a vacuum having a pressure of 1 mTorr or 10 Torr, for example.

The chamber interior 1632 includes substrate support features 1635 that are configured to support and thermally float a substrate 1634 in the chamber. The substrate support features 1635 may include clamps, horizontal pins or supports, vertical pins or supports, and semi-circular rings, for instance, that support the substrate 1634 in the chamber interior 1632. These features are configured to support the substrate 1634 such that the thermal mass of the substrate 1634 is reduced as much as possible to the thermal mass of just the substrate. Each substrate support feature 1635 may therefore have minimal contact with the substrate 1634 and may be the smallest number of features required to adequately support the substrate during processing (e.g., in order to support the weight of the substrate and prevent inelastic deformation of the substrate). For instance, the surface area of one substrate support feature 1635 in contact with a substrate may be less than about 1%, 0.5%, 0.1%, 0.05%, or 0.01% of the overall surface area of the back side of the substrate; also, for instance, 2, 3, or 4 features may be utilized.

In one example, the support features 1635 may include two or more vertical pins that have grooves wrapped or spiraled along the vertical, longitudinal axis and that are offset at varying distances from the longitudinal axis and configured to support a substrate. When the vertical pin rotates along its longitudinal axis and the edge of a substrate is positioned in the groove, the edge of the groove, and therefore the edge of the substrate, moves farther away from the longitudinal axis. When multiple vertical pins are used to support a substrate, the rotation of the vertical pins causes the grooves to apply a supporting force to the substrate in a direction perpendicular to the longitudinal axis.

In some embodiments, the chamber 1622 may include a wafer support pedestal that includes substrate lift pins. During thermal ALE processing, the lift pins may support and position the substrate away from the pedestal such that there is substantially no transference of thermal energy between the pedestal and substrate (e.g., less than 10%, 5%, 1%, 0.5%, or 0.1% of energy transferred between the two). In some other embodiments, the chamber 1622 may not have a pedestal. In some embodiments, an electrostatic chuck (ESC) may be used that contains substrate heating unit 1626 configured to heat the substrate to temperatures provided herein, such as between about 20° C. and 500° C.

The substrate heating unit 1626 is configured to heat the substrate to multiple temperatures and maintain such temperatures for at least 1 second, 5 seconds, 10 seconds, 30 seconds, 1 minute, 2 minutes, or 3 minutes, for example. In some embodiments, the substrate heating unit 1626 is configured to heat the substrate between at least two temperature ranges, with the first range between about 20° C. and 150° C., and the second range between about 200° C. and 600° C., as well as configured to maintain the substrate at a temperature within these ranges for at least 1 second, 5 seconds, or 10 seconds, for example. Additionally, in some embodiments, the substrate heating unit 1626 is configured to heat the substrate from the first temperature range to the second temperature range in less than about 250 milliseconds, 150 milliseconds, 100 milliseconds, or 50 milliseconds, for instance.

The substrate heating unit 1626 may utilize radiant heating, convective heating, laser heating, plasma heating, solid-to-solid thermal transference (e.g., transferring heat generated by one or more heating elements in a heated electrostatic chuck or pedestal to a substrate supported by or on that chuck or pedestal), or a combination of these items. For radiant heating, the substrate heating unit 1626 may be used for emitted light heating, ultraviolet heating, microwave heating, radio frequency heating, and induction heating. For example, the substrate heating unit 1626 may include light emitting diodes (LEDs) that emit visible light with wavelengths that may include and range between 400 nanometers (nm) and 800 nm. This may also include, for instance, a heat lamp, light emitting diodes (e.g., LEDs), a ceramic heater, a quartz heater, or a plurality of Gradient Index (GRIN) Lenses connected to a light energy source. A GRIN lens is configured to deliver heat energy (thermal or light) from the light energy source to the substrate in a uniform manner; the light source may be a laser or high-intensity light source that transmits the heat energy through a conduit, such as a fiber optic cable, to the GRIN lenses. The heating elements utilized by the substrate heating unit 1626 may be positioned above, below, on the side, or a combination of the positions, the substrate 1634, and they may be positioned inside, outside, or both, the chamber interior 1632. In FIG. 16, the heating elements utilized by the substrate heating unit 1626 include a plurality of LEDs 1626A that are positioned both above and below the substrate 1634; the lower heating elements are positioned inside the chamber interior 1632 and the upper heating elements are positioned outside the chamber interior 1632. In some embodiments, for some of the heating elements that are positioned outside the chamber 1622, the chamber 1622 may have a window 1654 that allows for the radiation to be transmitted into the chamber interior 1632 and onto the substrate 1634. In some embodiments, this window 1654 may be an optical-grade quartz plate while in other embodiments it may be a transparent indium tin oxide (ITO) window. In some embodiments, the substrate heating unit 1626 include a plurality of LEDs 1626A may only be positioned underneath the substrate 1634, which may include inside a pedestal or ESC that also may include a window through which the light emitted by the LEDs may reach the backside of the substrate.

For solid-to-solid thermal transference, the substrate heating unit 1626 may have one or more heating surfaces that are configured to contact and heat the substrate in the chamber interior. In some embodiments, the substrate heating unit 1626 may have a heating platen, such as a flat surface or a surface of a substrate pedestal, that is configured to contact the back surface of the substrate and heat the substrate. This heating platen may have heating elements such as a heating coil, heating fluid, or radiative heating discussed above, that may heat the surface of the heating platen. The substrate may be heated when the back of the substrate is in direct contact with, or is offset from the heating platen but close enough to receive thermal energy from, the heating platen. When using this solid-to-solid thermal transference to heat the substrate, the substrate is separated from the heating platen when it is cooled. While some conventional ALE apparatuses may have a substrate pedestal that includes both heating and cooling elements, these apparatuses are unable to quickly (e.g., under 250 milliseconds) cycle between the temperatures of thermal ALE because of the large thermal masses of the pedestal that are repeatedly heated and cooled. For instance, it may take multiple seconds or minutes to heat a pedestal from a first temperature range (e.g., 20° C. to 100° C.) to a second temperature range (e.g., 200° C. to 500° C.), as well as to cool the pedestal from the second temperature range to a lower temperature that can cool the substrate to the first temperature range. Accordingly, after using this solid-to-solid heating technique, the heating platen and the substrate are separated from each other which may be accomplished, for instance, by moving the substrate and/or the heating platen away from each other. Without this separation, cooling occurs of both the thermal mass of the substrate and the heating platen which increases the cooling time which decreases substrate throughput. In some embodiments, an ESC or pedestal having the substrate heating unit and a Peltier element for cooling may enable fast heating and cooling times (such as about 30 seconds to cool a substrate to a desired temperature). In some embodiments, this may be performed at low pressures, such as less then 1 Torr, including less than 50 mTorr, for example.

The substrate cooling unit 1628 of FIG. 16 is configured to actively cool the substrate. In some embodiments, the substrate cooling unit 1628 flows a cooling gas onto the substrate 1634 which actively cools the substrate 1634. The substrate cooling unit 1628 may include a cooling fluid source 1648 which may contain a cooling fluid (a gas or a liquid), and a cooler 1650 configured to cool the cooling fluid to a desired temperature, such as less than or equal to 0° C., −50° C., −100° C., −150° C., −170° C., −200° C., and −250° C., for instance. The substrate cooling unit 1628 includes piping and coolant flow features 1652, e.g., nozzles or holes, that are configured to flow the coolant fluid into the chamber interior 1632. In some embodiments, the fluid may be in liquid state when it is flowed to the chamber 1622 and may turn to a vapor state when it reaches the chamber interior 1632, for example if the chamber interior 1632 is at a low pressure state, such as 1 Torr, for instance. The cooling fluid may be an inert element, such as nitrogen, argon, helium. In some embodiments, the flow rate of the cooling fluid into the chamber interior 1632 may be at least 10 liters per second, 50 liters per second, 100 liters per second, 150 liters per second, 200 liters per second, 250 liters per second, and 300 liters per second, for example.

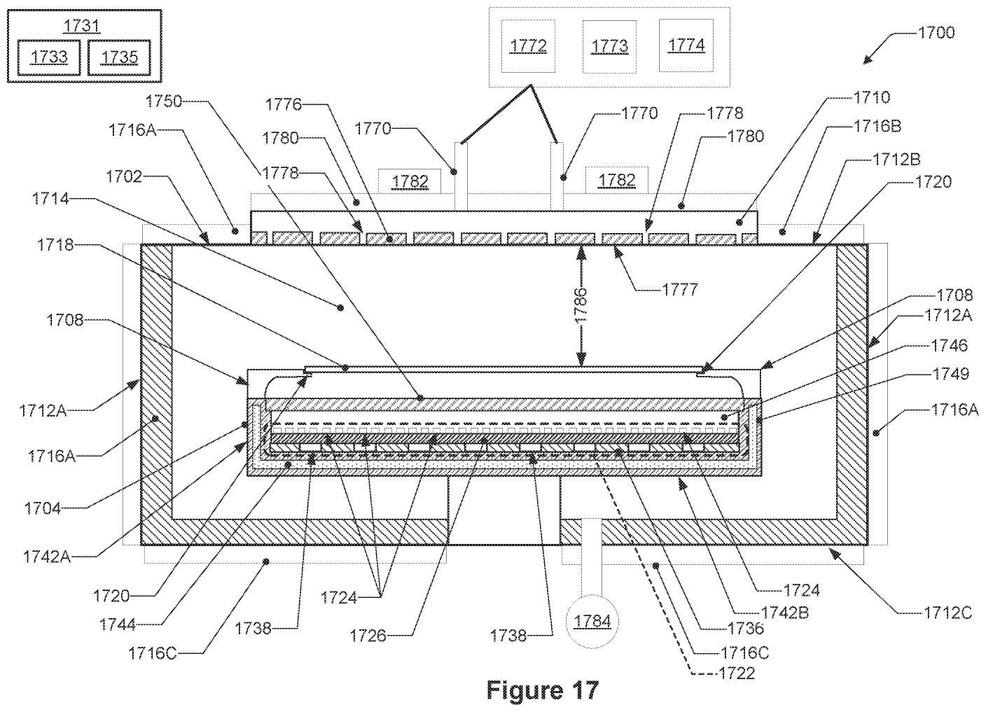

Various factors may increase the ability of the cooling fluid to cool the substrate. It has been discovered through various experiments that the higher the flow rate of the cooling fluid, the faster the substrate is cooled. In one example experiment, a cooling gas at about −196° C. flowed onto a substrate at a flow rate of 1 liter per second was found to reduce the temperature of a substrate from about 220° C. to about 215° C. in about 5,000 milliseconds, while the same cooling gas a flow rate of 10 liters per second reduced the temperature of a substrate from about 220° C. to about 195° C. in about 5,000 milliseconds. It was also discovered that a gap (1786 in FIG. 17) between the substrate and the top of the chamber may also affect the cooling of the substrate; the smaller the gap, the higher the cooling. In one instance, it was discovered that a substrate separated from the top of the chamber by a gap of about 50 micrometers was cooled from about 220° C. to about 215° C. in about 5,000 milliseconds using a cooling gas at about −196° C., while a substrate separated from the top of the chamber by a gap of about 5 millimeters was cooled from about 220° C. to about 209° C. in about 5,000 milliseconds using the same cooling gas. Accordingly, it was discovered that the higher the flow rate and the smaller the gap, the faster the substrate is cooled.

In some embodiments, the substrate cooling unit 1628 may use solid-to-solid thermal transference to actively cool the substrate 1634. In some of these embodiments, a cooling platen, such as a flat, cooled surface may be used to contact the bottom of the substrate and cool the substrate. This platen may be cooled by flowing a cooling fluid on, through, or underneath the platen. When using this solid-to-solid cooling, similar to the solid-to-solid heating discussed above, the substrate is separated from the cooling platen during heating of the substrate, such as by moving the substrate away from the cooling platen by, for instance, raising it up with lift pins. Without this separation, both the thermal masses of the substrate and cooling platen are cooled which requires more cooling that in turn increases process time and decreases throughput. In some embodiments, radiant heating of the top of the substrate or plasma heating of the bottom of the substrate may be used in conjunction with solid-to-solid cooling.

In some embodiments, the substrate cooling unit 1628 may use laser cooling to cool the substrate. This may enable the cooling of a substrate that includes thulium molecules on at least the exposed surface of the substrate by utilizing a reverse Navier-Stokes reaction. For example, the temperature of the substrate manifests itself in phonons and the laser cooling emits photons to the substrate surface which interact with and pick-up phonons in the thulium, and then leave the substrate with the phonon from the thulium at a higher energy level. The removal of these phonons causes a decrease in the temperature of the substrate. The thulium may be doped onto the surface of the substrate in order to enable this laser cooling, and this doping may be incorporated into the techniques listed above, such as occurring after or before any operation, such as the removal operation.

As noted above, some embodiments of the apparatus may include a plasma source configured to generate a plasma within the chamber interior. These plasma sources may be a capacitively coupled plasma (CCP), an inductively coupled plasma (ICP), an upper remote plasma, and a lower remote plasma.

In some embodiments, the apparatuses described herein may include a controller that is configured to control various aspects of the apparatus in order to perform the techniques described herein. For example, in FIG. 16, apparatus 1620 includes a controller 1666 (which may include one or more physical or logical controllers) that is communicatively connected with and that controls some or all of the operations of a processing chamber. The system controller 1666 may include one or more memory devices 1668 and one or more processors 1670. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 1650 ms. Switching time may depend on the flow chemistry, recipe chosen, reactor architecture, and other factors.

In some implementations, the controller 1666 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 1666, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 1666 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 1666, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 1666 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 1666 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 1666 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. For instance, referring to apparatus 1620 of FIG. 16 and technique of FIG. 1, in some embodiments the controller 1666 is configured to cause the substrate heating unit 1626 to bring (i.e., heat) the wafer 1634 positioned on the substrate support features 1635 to a first temperature, and cause the process gas unit 1624 to flow the first process gas to the wafer 1634. As noted above, the first process gas is configured to modify one or more surface layers of the chalcogenide on the wafer 1634 by chemical adsorption, without using a plasma in some embodiments, while the wafer is maintained at the first temperature. The controller 1666 may further be configured to cause the process gas unit to flow the second process gas onto the wafer 1634 as described herein to remove the modified layer of chalcogenide. Some implementations include the controller 1666 causing one or more layers of encapsulation material to be deposited onto the wafer 1634 as provided herein.

As noted above, some etching performed herein may be temperature controlled features of the processing chamber, such as its side walls, top, and/or bottom, as well as the showerhead and gas delivery system. FIG. 17 depicts a cross-sectional side view of an example apparatus in accordance with disclosed embodiments. As detailed below, this apparatus 1700 is capable of rapidly and precisely controlling the temperature of a substrate, including performing thermal etching operations. The apparatus 1700 includes a processing chamber 1702, a pedestal 1704 having a substrate heater 1706 and a plurality of substrates supports 1708 configured to support a substrate 1718, and a gas distribution unit 1710.

The processing chamber 1702 includes sides walls 1712A, a top 1712B, and a bottom 1712C, that at least partially define the chamber interior 1714, which may be considered a plenum volume. As stated herein, it may be desirable in some embodiments to actively control the temperature of the processing chamber walls 1712A, top 1712B, and bottom 1712C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 1712A, the top 1712B, and the bottom 1712C. As illustrated in FIG. 17, chamber heaters 1716A are positioned on and configured to heat the chamber walls 1712A, chamber heaters 1716B are positioned on and configured to heat the top 1712B, and chamber heaters 1716C are positioned on and configured to heat the bottom 1712C. The chamber heaters 1716A-1716C may be resistive heaters that are configured to generate heat when an electrical current is flowed through a resistive element. Chamber heaters 1716A-1716C may also be fluid conduits through which a heat transfer fluid may be flowed, such as a heating fluid which may include heated water. In some instances, the chamber heaters 1716A-1716C may be a combination of both heating fluid and resistive heaters. The chamber heaters 1716A-1716C are configured to generate heat in order to cause the interior surfaces of each of the chamber walls 1712A, the top 1712B, and the bottom 1712C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 1712A, top 1712B, and bottom 1712C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anhydrous HF, water vapor, methanol, isopropyl alcohol, chlorine, fluorine gases, nitrogen gas, hydrogen gas, helium gas, and the mixtures thereof.

The apparatus 1700 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 1784 configured to pump the chamber interior 1714 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 1704 will now be discussed. The pedestal 1704 includes a heater 1722 (encompassed by the dashed rectangle in FIG. 17) that has a plurality of LEDs 1724 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon wafers from ambient temperature, e.g., about 20° C., to about 600° C. because silicon absorbs light within this range. In contrast, radiant, including infrared radiant, heating may ineffectively heat silicon at temperatures up to about 400° C. because silicon tends to be transparent to infrared at temperatures lower than about 400° C. Traditional “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat a traditional pedestal to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip is typically limited to having three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

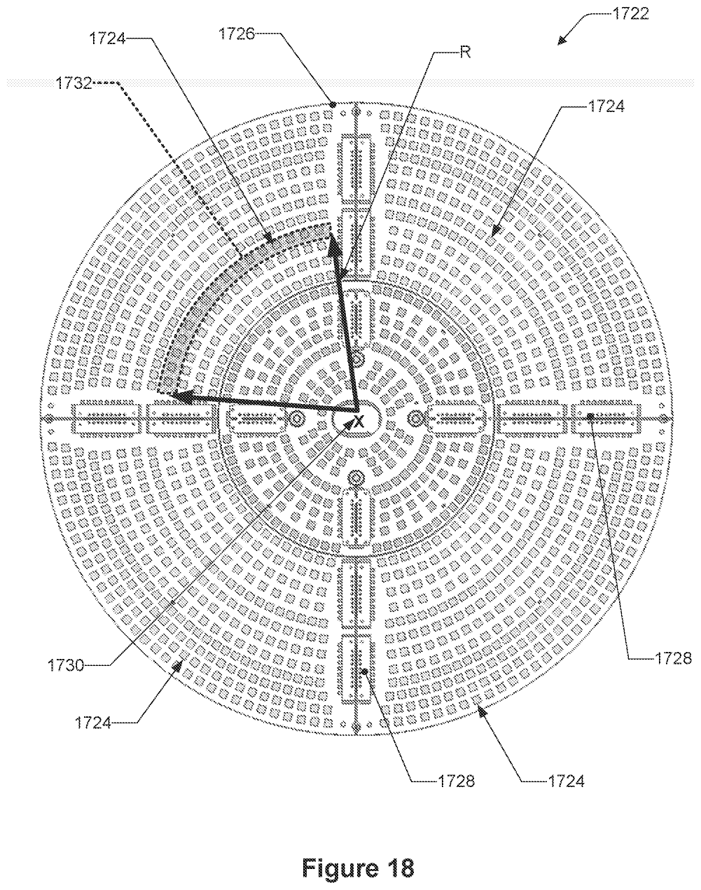

FIG. 18 depicts a top view of a substrate heater with a plurality LEDs. This substrate heater 1722 includes a printed circuit board 1726 and the plurality of LEDs 1724, some of which are labeled; this depicted plurality includes approximately 1,300 LEDs. External connections 1728 are connected by traces to provide power to the plurality of LEDs 1724. As illustrated in FIG. 18, the LEDs may be arranged along numerous arcs that are radially offset from the center 1730 of the substrate heater 1722 by different radiuses; in each arc, the LEDs may be equally spaced from each other. For example, one arc 1732 is surrounded by a partially shaded dotted shape, includes 16 LEDs 1724, and is a part of a circle with a radius R that extends around the center 1730. The 16 LEDs 1724 may be considered equally spaced from each other along this arc 1732.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses 4 watts or less at 100% power, including 3 watts at 100% power and 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (i.e., an annular sector), an arc, a segment, and a sector that may be centered on the center of the heater and have a radius less than or equal to the overall radius of the substrate heater's PCB. These zones are able to adjust the temperature at numerous locations across the wafer in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 1722 is configured to heat the substrate to multiple temperatures and maintain each such temperatures for various durations. These durations may include the following non-limiting examples of at least about 1 second, at least about 5 seconds, at least about 10 seconds, at least about 30 seconds, at least about 60 seconds, at least about 90 seconds, at least about 120 second, at least about 150 seconds, or at least about 180 seconds. The substrate heater may be configured to heat the substrate to between about 50° C. and 600° C., including between about 50° C. and 150° C., including about 130° C., or between about 150° C. and 350° C., for example. The substrate heater may be configured to maintain the substrate at a temperature within these ranges for various durations, including the following non-limiting examples: at least about 1 second, at least about 5 seconds, at least about 10 seconds, at least about 30 seconds, at least about 60 seconds, at least about 90 seconds, at least about 120 seconds, at least about 150 seconds, or at least about 180 seconds, for example. Additionally, in some embodiments, the substrate heater 1722 is configured to heat the substrate to any temperature within these ranges in less than about 60 seconds, less than about 45 seconds, less than about 30 seconds, or less than about 15 seconds, for instance. In certain embodiments, the substrate heater 1722 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit between about 10 W and 4000 W, including at least about 10 W, at least about 30 W, at least about 0.3 kilowatt (kW), at least about 0.5 kW, at least about 2 kW, at least about 3 kW, or at least about 4 kw. The apparatus is configured to supply between about 0.1 kw and 9 kW of power to the pedestal; the power supply is connected to the substrate heater through the pedestal but is not depicted in the Figures. During temperature ramps, the substrate heater may operate at the high powers, and may operate at the lower power levels (e.g., include between about 5 W and about 0.5 kW) to maintain the temperature of a heated substrate.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 17, the substrate heater includes a pedestal cooler 1736 in direct contact with the bottom of the PCB 1726. Heat is configured to flow from the LEDs, to the PCB 1726, and to the pedestal cooler 1736. The pedestal cooler 1736 also includes a plurality of fluid conduits 1738 through which a heat transfer fluid, such as water, is configured to flow in order to receive the heat and thus cool the LEDs in the substrate heater 1722. The fluid conduits 1738 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 1702. In some instances, it may similarly be advantageous to heat the exterior surfaces of the pedestal 1704 in order to prevent unwanted condensation and deposition on its external surfaces. As illustrated in FIG. 17, the pedestal 1704 may further include a pedestal heater 1744 inside of the pedestal 1704 that is configured to heat the exterior surfaces of the pedestal 1704, including its sides 1742A and bottom 1742B. The pedestal heater 1744 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 17, the window 1750 may be positioned above the substrate heater 1722 and may be sealed to the sidewall 1749 of the pedestal 1704 in order to create a plenum volume within the pedestal that is fluidically isolated from the chamber interior. This plenum volume may also be considered the inside of the bowl 1746. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of 15 to 30 mm, including 20 mm and 25 mm.

As shown in FIG. 17, the pedestal's 1704 substrate supports 1708 are configured to support the substrate 1718 above and offset from the window 1750 and the substrate heater 1722. In certain embodiments, the temperature of the substrate can be rapidly and precisely controlled by thermally floating, or thermally isolating, the substrate within the chamber. The heating and cooling of a substrate is directed at both the substrate's thermal mass and the thermal masses of other items in contact with the substrate. For instance, if the substrate is in thermal contact with a large body, such as the entirety of the substrate's back side resting on a large surface of a pedestal or electrostatic chuck as in many conventional etching apparatuses, this body acts as a heat sink for the substrate which affects the ability to accurately control the substrate temperature and reduces the quickness of substrate heating and cooling. It is therefore desirable to position the substrate so that the smallest thermal mass is heated and cooled. This thermal floating is configured to position the substrate so that it has minimal thermal contact (which includes direct and radiation) with other bodies in the chamber.

The pedestal 1704 is therefore configured, in some embodiments, to support the substrate 1718 by thermally floating, or thermally isolating, the substrate within the chamber interior 1714. The pedestal's 1704 plurality of substrate supports 1708 are configured to support the substrate 1718 such that the thermal mass of the substrate 1718 is reduced as much as possible to the thermal mass of just the substrate 1718. Each substrate support 1708 may have a substrate support surface 1720 that provides minimal contact with the substrate 1718. The number of substrate supports 1708 may range from at least 3 to, for example, at least 6 or more. The surface area of the support surfaces 1720 may also be the minimum area required to adequately support the substrate during processing operations (e.g., in order to support the weight of the substrate and prevent inelastic deformation of the substrate). In some embodiments, the surface area of one support surface 1720 may be less than about 0.1%, less than about 0.075%, less than about 0.05%, less than about 0.025%, or less than about 0.01%, for instance.

The substrate supports are also configured to prevent the substrate from being in contact with other elements of the pedestal, including the pedestal's surfaces and features underneath the substrate. The substrate 1718 is also offset from the substrate heater 1722 (as measured in some instances from a top surface of the substrate heater 1722 which may be the top surface of the LEDs 1724) by a distance which may affect numerous aspects of heating the substrate 1718.

As stated, the substrate supports 1708 are configured to support the substrate 1718 above the window. In some embodiments, these substrate supports are stationary and fixed in position; they may not be lift pins or a support ring. In some embodiments, at least a part of each substrate support 1708 that includes the support surface 1720 may be comprised of a material that is transparent at least to light emitted by LEDs 1724. This material may be, in some instances, quartz or sapphire. The transparency of these substrate supports 1708 may enable the visible light emitted by the substrate heater's 1722 LEDs to pass through the substrate support 1708 and to the substrate 1718 so that the substrate support 1708 does not block this light and the substrate 1718 can be heated in the areas where it is supported. This may provide a more uniform heating of the substrate 1718 than with a substrate support comprising a material opaque to visible light. In some other embodiments, the substrate supports 1708 may be comprised of a non-transparent material, such as zirconium dioxide (ZrO₂).

Referring back to FIG. 17, in some embodiments, the pedestal is also configured to move vertically. This may include moving the pedestal such that a gap 1786 between a faceplate 1776 of the gas distribution unit 1710 and the substrate 1718 is capable of being in a range of 2 mm and 70 mm. As provided in more detail below, moving the pedestal vertically may enable active cooling of the substrate as well as rapid cycling time of processing operations, including flowing gas and purging, due to a low volume created between the gas distribution unit 1710 and the substrate 1718. This movement may also enable the creation of a small process volume between the substrate and the gas distribution unit which can result in a smaller purge and process volume and thus reduce purge and gas movement times and increase throughput.

The gas distribution unit 1710 is configured to flow process gases, which may include liquids and/or gases, such as a reactant, modifying molecules, converting molecules, or removal molecules, onto the substrate 1718 in the chamber interior 1714. As seen in FIG. 17, the gas distribution unit 1710 includes one or more fluid inlets 1770 that are fluidically connected to one or more gas sources 1772 and/or one or more vapor sources 1774. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 1710 also includes the faceplate 1776 that includes a plurality of through-holes 1778 that fluidically connect the gas distribution unit 1710 with the chamber interior 1714. These through-holes 1778 are fluidically connected to the one or more fluid inlets 1770 and also extend through a front surface 1777 of the faceplate 1776, with the front surface 1777 configured to face the substrate 1718. In some embodiments, the gas distribution unit 1710 may be considered a top plate and in some other embodiments, it may be considered a showerhead.

The through-holes 1778 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 17, the gas distribution unit 1710 may also include a unit heater 1780 that is thermally connected to the faceplate 1776 such that heat can be transferred between the faceplate 1776 and the unit heater 1780. The unit heater 1780 may include fluid conduits in which a heat transfer fluid may be flowed. Similar to above, the heat transfer fluid may be heated to a temperature range of about 20° C. and 120° C., for example. In some instances, the unit heater 1780 may be used to heat the gas distribution unit 1710 to prevent unwanted condensation of vapors and gases; in some such instances, this temperature may be at least about 90° C. or 120° C.

In some embodiments, the gas distribution unit 1710 may include a second unit heater 1782 that is configured to heat the faceplate 1776. This second unit heater 1782 may include one or more resistive heating elements, fluid conduits for flowing a heating fluid, or both. Using two heaters 1780 and 1782 in the gas distribution unit 1710 may enable various heat transfers within the gas distribution unit 1710. This may include using the first and/or second unit heaters 1780 and 1782 to heat the faceplate 1776 in order to provide a temperature-controlled chamber, as described above, in order to reduce or prevent unwanted condensation on elements of the gas distribution unit 1710.

The apparatus 1700 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 1780 that flows the heat transfer fluid through fluid conduits may be used to cool the substrate 1718 by transferring heat away from the faceplate 1776 that is transferred from the substrate 1719. A substrate 1718 may therefore be cooled by positioning it in close proximity to the faceplate 1776, such as by a gap 1786 of less than or equal to 5 mm or 2 mm, such that the heat in the substrate 1718 is radiatively transferred to the faceplate 1776, and transferred away from the faceplate 1776 by the heat transfer fluid in the first unit heater 1780. The faceplate 1776 may therefore be considered a heat sink for the substrate 1718 in order to cool the substrate 1718.

In some embodiments, the apparatus 1700 may further include a cooling fluid source 1773 which may contain a cooling fluid (a gas or a liquid), and a cooler (not pictured) configured to cool the cooling fluid to a desired temperature, such as less than or equal to at least about 90° C., at least about 70° C., at least about 50° C., at least about 20° C., at least about 10° C., at least about 0° C., at least about −50° C., at least about −100° C., at least about −150° C., at least about −190° C., at least about −200° C., or at least about −250° C., for instance. The apparatus 1700 includes piping to deliver the cooling fluid to the one or more fluid inlets 1770, and the gas distribution unit 1710 which is configured to flow the cooling fluid onto the substrate. In some embodiments, the fluid may be in liquid state when it is flowed to the chamber 1702 and may turn to a vapor state when it reaches the chamber interior 1714, for example if the chamber interior 1714 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In some embodiments, the flow rate of the cooling fluid into the chamber interior 1714 may be at least about 0.25 liters per minute, at least about 0.5 liters per minute, at least about 1 liters per minute, at least about 5 liters per minute, at least about 10 liters per minute, at least about 50 liters per minute, or at least about 100 liters per minute, for example. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 1700 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

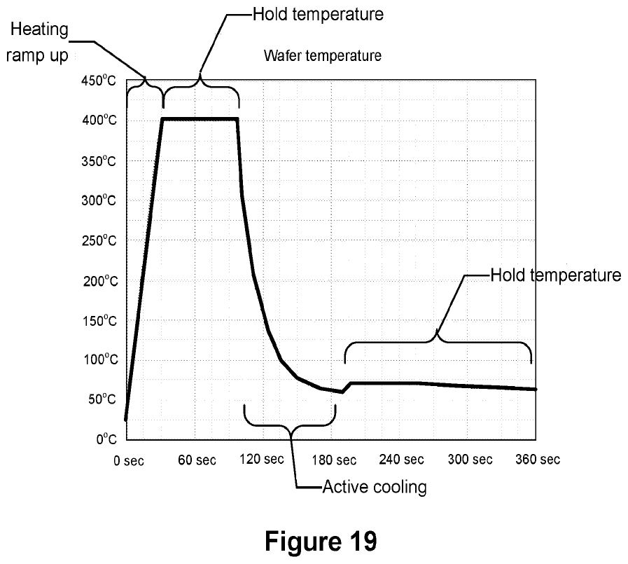

The apparatuses provided herein can therefore rapidly heat and cool a substrate. FIG. 19 provides an example temperature control sequence. At time 0, the substrate is at approximately 20 or 25° C., and the LEDs of the substrate heater provided herein emit the visible light having wavelengths between 400 nm and 800 nm and cause the substrate temperature to rise to about 400° C. in approximately 30 seconds. This heating was accomplished using between 1 kW and 2 kW of heating power that is provided by approximately 9 kW of supplied power to the substrate heater. From about 30 seconds to about 95 seconds, the substrate heater 1722 held the substrate at 400° C. using less power, such as 0.3 to about 0.5 kW of heating power provided by approximately 2 kW of supplied power. For about 30 to 60 seconds, the substrate was actively cooled using both cooling gas flowed onto the substrate (e.g., hydrogen or helium) and heat transfer to the faceplate. Once cooled, the substrate heater heated the substrate to hold its temperature at approximately 70° C. using between about 10 and 30 W of heating power provided by about 100 W of supplied power. Various processing techniques may use this type of sequence, either once or repeatedly, for processing a substrate.

In some embodiments, the apparatus 1700 may include a mixing plenum for blending and/or conditioning process gases for delivery before reaching the fluid inlets 1770. One or more mixing plenum inlet valves may control introduction of process gases to the mixing plenum. In some other embodiments, the gas distribution unit 1710 may include one or more mixing plenums within the gas distribution unit 1710. The gas distribution unit 1710 may also include one or more annular flow paths fluidically connected to the through-holes 1778 which may equally distribute the received fluid to the through-holes 1778 in order to provide uniform flow onto the substrate.

Apparatus 1700 includes a controller 1731, which may be the same as controller 1666 and which may include one or more physical or logical controllers, that is communicatively connected with and that controls some or all of the operations of a processing chamber, and is able to perform any of the processes described herein.

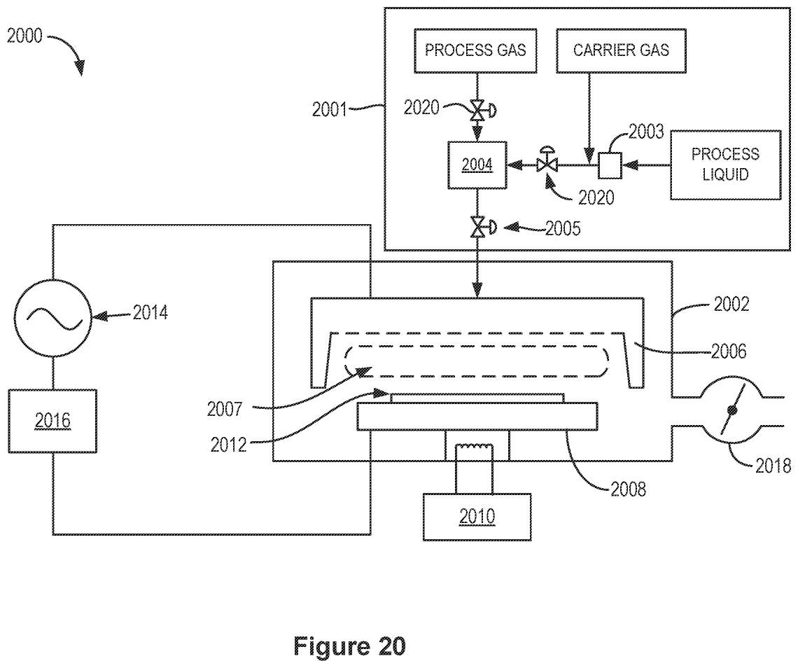

FIG. 20 schematically shows an embodiment of a process station 2000 that may be used to deposit material using atomic layer deposition (ALD) and/or chemical vapor deposition (CVD), either of which may be plasma enhanced. For simplicity, the process station 2000 is depicted as a standalone process station having a process chamber body 2002 for maintaining a low-pressure environment. However, it will be appreciated that a plurality of process stations 2000 may be included in a common process tool environment. Further, it will be appreciated that, in some embodiments, one or more hardware parameters of process station 2000, including those discussed in detail below, may be adjusted programmatically by one or more computer controllers.

Process station 2000 fluidly communicates with reactant delivery system 2001 for delivering process gases to a distribution showerhead 2006. Reactant delivery system 2001 includes a mixing vessel 2004 for blending and/or conditioning process gases for delivery to showerhead 2006. One or more mixing vessel inlet valves 2020 may control introduction of process gases to mixing vessel 2004. Similarly, a showerhead inlet valve 2005 may control introduction of process gasses to the showerhead 2006.

Some reactants, like BTBAS, may be stored in liquid form prior to vaporization at and subsequent delivery to the process station. For example, the embodiment of FIG. 20 includes a vaporization point 2003 for vaporizing liquid reactant to be supplied to mixing vessel 2004. In some embodiments, vaporization point 2003 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 2003 may be heat traced. In some examples, mixing vessel 2004 may also be heat traced. In one non-limiting example, piping downstream of vaporization point 2003 has an increasing temperature profile extending from approximately 100° C. to approximately 150° C. at mixing vessel 2004.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 2003. In one scenario, a liquid injector may be mounted directly to mixing vessel 2004. In another scenario, a liquid injector may be mounted directly to showerhead 2006.

In some embodiments, a liquid flow controller upstream of vaporization point 2003 may be provided for controlling a mass flow of liquid for vaporization and delivery to process station 2000. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 2006 distributes process gases toward substrate 2012. In the embodiment shown in FIG. 20, substrate 2012 is located beneath showerhead 2006, and is shown resting on a pedestal 2008. It will be appreciated that showerhead 2006 may have any suitable shape, and may have any suitable number and arrangement of ports for distributing processes gases to substrate 2012.

In some embodiments, a microvolume 2007 is located beneath showerhead 2006. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 2008 may be raised or lowered to expose substrate 2012 to microvolume 2007 and/or to vary a volume of microvolume 2007. For example, in a substrate transfer phase, pedestal 2008 may be lowered to allow substrate 2012 to be loaded onto pedestal 2008. During a deposition process phase, pedestal 2008 may be raised to position substrate 2012 within microvolume 2007. In some embodiments, microvolume 2007 may completely enclose substrate 2012 as well as a portion of pedestal 2008 to create a region of high flow impedance during a deposition process.

Optionally, pedestal 2008 may be lowered and/or raised during portions the deposition process to modulate process pressure, reactant concentration, etc., within microvolume 2007. In one scenario where process chamber body 2002 remains at a base pressure during the deposition process, lowering pedestal 2008 may allow microvolume 2007 to be evacuated. Example ratios of microvolume to process chamber volume include, but are not limited to, volume ratios between 1:2000 and 1:10. It will be appreciated that, in some embodiments, pedestal height may be adjusted programmatically by a suitable computer controller.

In another scenario, adjusting a height of pedestal 2008 may allow a plasma density to be varied during plasma activation and/or treatment cycles included in the deposition process. At the conclusion of the deposition process phase, pedestal 2008 may be lowered during another substrate transfer phase to allow removal of substrate 2012 from pedestal 2008.

While the example microvolume variations described herein refer to a height-adjustable pedestal, it will be appreciated that, in some embodiments, a position of showerhead 2006 may be adjusted relative to pedestal 2008 to vary a volume of microvolume 2007. Further, it will be appreciated that a vertical position of pedestal 2008 and/or showerhead 2006 may be varied by any suitable mechanism within the scope of the present disclosure. In some embodiments, pedestal 2008 may include a rotational axis for rotating an orientation of substrate 2012. It will be appreciated that, in some embodiments, one or more of these example adjustments may be performed programmatically by one or more suitable computer controllers.

In some embodiments, the processing chamber in FIG. 2000 does not use a plasma for the ALD deposition and therefore does not have plasma-related equipment. In some other embodiments, a plasma may be used or the reactor may have such plasma-related equipment. For example, as shown in FIG. 20, showerhead 2006 and pedestal 2008 electrically communicate with RF power supply 2014 and matching network 2016 for powering a plasma. In some embodiments, the plasma energy may be controlled by controlling one or more of a process station pressure, a gas concentration, an RF source power, an RF source frequency, and a plasma power pulse timing. For example, RF power supply 2014 and matching network 2016 may be operated at any suitable power to form a plasma having a desired composition of radical species. Examples of suitable powers are included above. Likewise, RF power supply 2014 may provide RF power of any suitable frequency. In some embodiments, RF power supply 2014 may be configured to control high- and low-frequency RF power sources independently of one another. Example low-frequency RF frequencies may include, but are not limited to, frequencies between 50 kHz and 2000 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 2008 may be temperature controlled via heater 2010. In some embodiments, the heater 2010 may be the same as the heater unit described above and shown in FIGS. 16-18, such as a heater unit that includes a plurality of LEDs used to heat the wafer. Further, in some embodiments, pressure control for deposition process station 2000 may be provided by butterfly valve 2018. As shown in the embodiment of FIG. 20, butterfly valve 2018 throttles a vacuum provided by a downstream vacuum pump (not shown). However, in some embodiments, pressure control of process station 2000 may also be adjusted by varying a flow rate of one or more gases introduced to process station 2000.

Although FIG. 20 is depicted as a single station, it will be appreciated that a processing chamber may have multiple such stations that share gas delivery systems or other equipment. For example, as shown in FIGS. 10 and 12, chambers 1004, 1006, 1202, and 1204 include four processing stations. Each station may include any and all of the features described with respect to the single stations in FIGS. 16-18 and 20. The stations in chambers 1004 and 1202 may be used for etching and the stations in chambers 1006 and 1204 may be used for depositing material on the wafer. For instance, each station of chambers 1004 and 1202 may be used to perform thermal etching, such as thermal ALE, on a wafer held in a wafer holder, such as a pedestal, at a particular process station; similarly each station of chambers 1006 and 1204 may be used to perform deposition, such as ALD and thermal ALD, on a wafer held in a wafer holder at a particular process station. Other similar multi-station processing apparatuses may have more or fewer process stations depending on the implementation and, for example, a desired level of parallel wafer processing, size/space constraints, cost constraints, etc.

For some processing chambers, such as deposition chambers 1006 and 1204 in FIGS. 10 and 12, respectively, an RF subsystem 1090 and 1290 may generate and convey RF power to integrated circuit fabrication chamber 1006 and 1204 via radio frequency input ports. In particular embodiments, integrated circuit fabrication chambers 1006 and 1204 may comprise input ports in addition to radio frequency input ports. Accordingly, integrated circuit fabrication chambers 1006 and 1204 may utilize 8 RF input ports. In particular embodiments, process stations 1082A-D and 1282A-D of integrated circuit fabrication chambers 1006 and 1204 may each utilize first and second input ports in which a first input port may convey a signal having a first frequency and in which a second input port may convey a signal having a second frequency. Use of dual frequencies may bring about enhanced plasma characteristics.

As provided above, a system controller may be employed on the tools described herein to control process conditions during etching and/or deposition. The controller, 1029 in FIG. 10, 1229 in FIGS. 12, and 1666 in FIG. 16, for example, will typically include one or more memory devices and one or more processors. The controller 1029 may control all of the activities of the tool 1000 and/or 1200. In some implementations, the controller 1029 and/or 1229 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The controller is configured to perform any technique described above. For instance, referring to apparatus 1000 of FIG. 10 or apparatus 1200 of FIG. 12, and technique of FIG. 1, in some embodiments the controller 1029 and/or 1229 is configured to cause the substrate heating unit to bring (i.e., heat) the wafer positioned on the substrate support features to a first temperature, and cause the process gas unit to flow the first process gas to the wafer. As noted above, the first process gas is configured to modify one or more surface layers of the chalcogenide on the wafer by chemical adsorption, without using a plasma in some embodiments, while the wafer is maintained at the first temperature. The controller may further be configured to cause the process gas unit to flow the second process gas onto the substrate as described herein to remove the modified layer of chalcogenide. Some implementations include the controller causing one or more layers of encapsulation material to be deposited onto the wafer as provided herein. The controller is further configured to cause the wafer transfer unit, including any of the robotic arms, to transport the wafer between any of the processing stations and to control the pressure units 1016 and 1216, which may include one or more vacuum pumps, to control the pressure within the tool and the chambers.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

1. A method comprising:
providing a wafer to a processing chamber, the wafer having a layer of a chalcogenide material;
heating the wafer to a first temperature; and
etching the layer of the chalcogenide material by modifying a surface of the layer of chalcogenide material by flowing a first chemical species comprising a fluoride or a chloride onto the wafer to create a modified layer of chalcogenide material while the wafer is at the first temperature, and removing the modified layer of chalcogenide material, without using a plasma, by flowing a second chemical species comprising a compound with a center atom that is aluminum, boron, silicon, or germanium, and with at least one chlorine, onto the wafer.

2. (canceled)

3. The method of claim 1, wherein the chalcogenide material comprises germanium antimony tellurium.

4. The method of claim 1, wherein the first chemical species comprises a hydrogen fluoride, a nitrogen fluoride, a sulfur fluoride, a xenon fluoride, a hydrogen chloride, a sulfur chloride, or a nitrogen chloride.

5. The method of claim 1, wherein the compound further comprises one or more of: a plurality of chlorine atoms, a hydrogen, a methyl group, or an ethyl group.

6. The method of claim 1, wherein the compound comprises one of dimethylaluminum chloride and trimethylaluminum chloride.

7. The method of claim 1, further comprising depositing, after the etching, an encapsulation material onto the etched layer of chalcogenide material.

8. (canceled)

9. (canceled)

10. The method of claim 7, wherein the encapsulation material comprises aluminum or silicon.

11. The method of claim 10, wherein:
the depositing includes flowing the second chemical species and water vapor onto the wafer.

12. (canceled)

13. (canceled)

14. The method of claim 10, further comprising:
transferring, after the etching and the depositing, the wafer to a second processing chamber, and
depositing, after the transferring, a second encapsulation material onto the encapsulation material, wherein the second encapsulation material comprises a silicon oxide or silicon nitride.

15. The method of claim 7, wherein:
the wafer further comprises a layer of a second chalcogenide material, and
the method further comprises:
etching, after the depositing, the layer of the second chalcogenide material by modifying a surface of the layer of the second chalcogenide material by flowing a third chemical species comprising a fluoride or a chloride onto the wafer to create a modified layer of the second chalcogenide material while the wafer is at the first temperature, and removing the modified layer of second chalcogenide material, without using a plasma, by flowing a fourth chemical species comprising a compound with a center atom that is aluminum, boron, silicon, or germanium, and with at least one chlorine, onto the wafer.

16. The method of claim 15, further comprising depositing, after the etching of the layer of the second chalcogenide material, a second encapsulation material onto the layer of second chalcogenide material.

17. (canceled)

18. The method of claim 1, wherein:
the modifying includes flowing a first process gas comprising the first chemical species, and
the removing includes flowing a second process gas comprising the second chemical species.

19. The method of claim 18, wherein flowing the first process gas onto the wafer at least partially overlaps with flowing the second process gas onto the wafer.

20. The method of claim 18, wherein flowing the first process gas does not overlap with flowing the second process gas onto the wafer.

21. The method of claim 20, wherein the etching further includes:
stopping the flow of the first process gas,
flowing, after stopping the flow of the first process gas, a purge gas onto the onto the wafer, and
starting the flow of the second process gas during or after the flowing of the purge gas.

22. (canceled)

23. (canceled)

24. (canceled)

25. (canceled)

26. The method of claim 1, wherein the modifying includes using a plasma.

27. (canceled)

28. (canceled)

29. The method of claim 1, wherein the modifying does not use a plasma.

30. (canceled)

31. The method of claim 1, wherein:
the modifying occurs while the wafer is maintained at the first temperature, and
the removing occurs while the wafer is maintained at a second temperature different than the first temperature.

32. (canceled)

33. (canceled)

34. (canceled)

35. (canceled)

36. The method of claim 1, wherein the modifying and the removing occur while the processing chamber is maintained at substantially the same pressure.

37. The method of claim 1, wherein:
the modifying occurs while the processing chamber is maintained at a first pressure, and
the removing occurs while the processing chamber is maintained at a second pressure different than the first pressure.

38. (canceled)

39. (canceled)

40. (canceled)

41. (canceled)

42. (canceled)

43. (canceled)

44. (canceled)

45. (canceled)
